(19) United States
(12) Patent Application Publication
(10) Pub. No.: US 2007/0232041 A1
(43) Pub. Date: Oct. 4, 2007

(54) Integrated circuit device gate structures having charge storing nano crystals in a metal oxide dielectric layer and methods of forming the same

(76) Inventors: Sam-jong Choi, Gyeonggi-do (KR); Kyoo-chul Cho, Gyeonggi-do (KR); Soo-yeol Choi, Gyeonggi-do (KR); Yong-kwon Kim, Gyeonggi-do (KR); Young-soo Park, Gyeonggi-do (KR); Chan-kook In, Gyeonggi-do (KR); Hae-jin Park, Gyeonggi-do (KR); Sang-Sig Kim, Seoul (KR)

Correspondence Address: Robert W. Glatz;Myers Bigel Sibley & Sajovec, P.A., P. O. Box 37428, Raleigh, NC, 27627, US

(21) Appl. No.: 11/510,058

(22) Filed: Aug. 25, 2006

(30) Foreign Application Priority Data
Apr. 4, 2006 (KR) 2006-30581

(51) Int. Cl. H01L 21/3205

(52) U.S. Cl. 438/585

(57) ABSTRACT

Methods of forming a gate structure for an integrated circuit memory device include forming a metal oxide dielectric layer on an integrated circuit substrate. Ions of a selected element from group 4 of the periodic table and having a thermal diffusivity of less than about 0.5 centimeters per second (cm²/s) are injected into the dielectric layer to form a charge storing region in the dielectric layer with a tunnel dielectric layer under the charge storing region and a capping dielectric layer above the charge storing region. The substrate including the metal oxide dielectric layer is thermally treated to form a plurality of discrete charge storing nano crystals in the charge storing region. A gate electrode layer is formed on the dielectric layer.

### CROSS-REFERENCE TO RELATED APPLICATION

This application is related to and claims priority under 35 U.S.C. § 119 from Korean Patent Application No. 10-2006-30581, filed on Apr. 4, 2006, in the Korean Intellectual Property Office, the disclosure of which is incorporated herein by reference in its entirety.

### BACKGROUND OF THE INVENTION

The present invention relates to integrated circuit devices and, more particularly, to gate structures of integrated circuit devices and methods of forming the same.

The increasing use of portable electronics and embedded systems has resulted in a need for low-power, high-density, non-volatile memories that can be programmed at very high speeds. One type of memory which has been developed is Flash electrically erasable programmable read only memory (Flash EEPROM). It is used in many portable electronic products, such as personal computers, cell phones, portable computers, voice recorders and the like as well as in many larger electronic systems, such as cars, planes, industrial control systems and the like.

A Flash EEPROM device is typically formed on an integrated circuit substrate, such as a semiconductor substrate. In portions of the surface of the substrate, a doped source region and a doped drain region are generally formed with a channel region therebetween. A tunnel silicon oxide dielectric layer may be formed on the semiconductor substrate over the channel region and between the source and drain regions. Above the tunnel silicon oxide dielectric layer, over the channel region, a stacked-gate structure is generally formed for a transistor having a floating gate layer, an inter-electrode dielectric layer and a control gate layer. The source region is typically located on one side of the stacked gate structure with one edge of the source region overlapping the gate structure. The drain region is generally located on the other side of the stacked gate structure with one edge overlapping the gate structure. The device may be, for example, programmed by hot electron injection and erased by Fowler-Nordheim tunneling as illustrated in FIG. 1.

A silicon (Si) nano crystal Flash EEPROM device has been proposed that can be programmed at fast speeds (hundreds of nanoseconds) using low voltages for direct tunneling and storage of electrons in the silicon nano crystals. By using nano crystal charge storage sites that are isolated electrically (discrete), charge leakage through localized defects in the gate oxide layer may be reduced as illustrated, for example, in FIG. 14. This may be contrasted with the continuous floating gate leakage path shown in FIG. 2.

A germanium (Ge) nano crystal Flash EEPROM device has also been proposed that can be programmed at low voltages and high speeds. Such a device may be fabricated by implanting germanium atoms into a silicon substrate. However, the implantation process can cause germanium to locate at the silicon-tunnel oxide interface, forming trap sites that can degrade the device performance. The presence of such trap sites places a lower limit to the thickness of the resulting tunnel oxide layer, because defect-induced leakage current in a very thin tunnel oxide can result in poor data retention performance.

A nano crystal charge trap triple layer structure having a tunneling oxide/Ge doped oxide/capping layer structure has also been proposed. Such a structure may have problems with a Capacitance-Voltage (CV) curve memory hysteresis characteristic drop, manufacturing process complication, leakage current and ion-out diffusion. The process complications may include difficulty in forming electron traps and a resulting overly thin tunnel oxide layer.

### SUMMARY OF THE INVENTION

Some embodiments of the present invention provide methods of forming a gate structure for an integrated circuit memory device including forming a metal oxide dielectric layer on an integrated circuit substrate. Ions of a selected element from group 4 of the periodic table and having a thermal diffusivity of less than about 0.5 centimeters per second (cm²/s) are injected into the dielectric layer to form a charge storing region in the dielectric layer with a tunnel dielectric layer under the charge storing region and a capping dielectric layer above the charge storing region. The substrate including the metal oxide dielectric layer is thermally treated to form a plurality of discrete charge storing nano crystals in the charge storing region. A gate electrode layer is formed on the dielectric layer.

In other embodiments, the metal oxide dielectric layer is an oxide and/or oxynitride of aluminum, hafnium, titanium, zirconium, scandium, yttrium and/or lanthanum having a dielectric constant of over 7 and the selected element is germanium (Ge). The ions may be injected at an injection energy of less than about 10000 electron volts (eV) and may be injected at an injection energy of greater than 5000 electron volts (eV). A thickness of the metal oxide dielectric layer formed on the substrate may be less than about 30 nm.

In further embodiments, injecting ions is preceded by thermally treating the substrate including the metal oxide dielectric layer. The thermal treatment may be at a temperature over a crystallization temperature of the metal oxide dielectric layer. The thermal treatment may be at a temperature at least about 950° C. in a nitrogen atmosphere.

In other embodiments, thermally treating the substrate after injecting ions includes rapid thermal annealing the substrate including the metal oxide dielectric layer at about 700° C. to about 900° C. for about 5 minutes to about 30 minutes. The rapid thermal annealing may be followed by a second rapid thermal annealing at about 900° C. to about 1050° C. for about 5 minutes to about 30 minutes. Thermally treating the substrate after injecting ions in some embodiments includes rapid thermal annealing the substrate including the metal oxide dielectric layer at about 900° C. to about 950° C. for about 5 minutes to about 30 minutes.

In yet other embodiments, a thickness of the metal oxide dielectric layer is less than about 30 nanometers (nm). A thickness of the tunnel dielectric layer may be less than about 9 nm. Injecting ions may include injecting the ions at a mean injection depth selected based on a thickness of the metal oxide dielectric layer and with a delta projection range of no more than about 7 nanometers (nm). Injecting ions may include injecting the ions with a delta projection range of from about 20 angstroms (Å) to about 60 Å. The metal oxide dielectric layer may have an energy band gap of at least about 5 electron volts (eV). Injecting ions may include injecting the ions at an ion injection energy of greater than 7000 electron volts (eV) and less than about 10000 eV and at an ion projection dose from about 1×10¹⁴/cm² to about 2×10¹⁶/cm². The nano crystals may have a diameter from about 1 nm to about 7 nm and a spacing between ones of the nano crystals may be between about 1 nm and about 7 nm.

In further embodiments, injecting ions includes injecting ions of the selected element at a first ion injection energy to form a first charge storing layer on the tunnel dielectric layer and injecting ions of the selected element at a second ion injection energy, less than the first ion injection energy, to form a second charge storing layer on the first charge storing layer with a region therebetween substantially free of implanted ions. Injecting ions may include injecting ions at a plurality of different height locations relative to the substrate in the metal oxide dielectric layer and thermally treating the substrate to provide a multi-layer structure of overlapping ones of the discrete charge storing nano crystals.

In other embodiments, forming the metal oxide dielectric layer is preceded by forming a common gate on a gate dielectric layer on the substrate. Forming the metal oxide dielectric layer, implanting ions and thermally treating are carried out on sidewalls of the common gate electrode and on a channel portion of the substrate proximate respective sides of the common gate. Forming the gate electrode layer includes forming sidewall gates on the second dielectric layer proximate the respective sides of the common gate and extending over the channel portion.

In further embodiments, wherein forming the metal oxide dielectric layer is preceded by forming a channel region including a recess region and a step region adjacent the recess region extending between a source and a drain region in the substrate. Forming the metal oxide dielectric layer, implanting ions, thermal treating and forming the gate electrode are carried out on the channel region including the recess region and the step region. The recess region may have a rounded portion. The integrated circuit device may be a non-volatile memory device or a dynamic random access memory (DRAM). The integrated circuit device may be a flash memory and the charge storing region may be a floating gate of a cell of the flash memory.

In yet further embodiments, the metal oxide dielectric layer is a first dielectric layer and the method further includes, between injecting ions and thermally treating the substrate, forming a second dielectric layer on the metal oxide dielectric layer, the second dielectric layer being a metal oxide. The second dielectric layer may have a thickness of less than about 10 nm. The first and second dielectric layer may be a same material. The first and second dielectric layer may be an oxide and/or oxynitride of aluminum, hafnium, titanium, zirconium, scandium, yttrium and/or lanthanum and the selected element may be germanium (Ge). The ions may be injected at an injection energy of less than about 10000 electron volts (eV) and may be injected at an injection energy of greater than 7000 electron volts (eV). A thickness of the metal oxide dielectric layer formed on the substrate may be less than about 20 nm.

In other embodiments, forming the second dielectric layer includes forming the second dielectric layer by atomic layer deposition (ALD) and/or plasma enhanced chemical vapor deposition (PECVD). In some embodiments including a common gate electrode, forming the first dielectric layer, implanting ions, thermally treating and forming the second dielectric layer are carried out on sidewalls of the common gate electrode and on a channel portion of the substrate proximate respective sides of the common gate and forming the gate electrode layer includes forming sidewall gates on the second dielectric layer proximate the respective sides of the common gate and extending over the channel portion. In some embodiments including a channel region including a recess region and a step region adjacent the recess region extending between a source and a drain region in the substrate, forming the first dielectric layer, implanting ions, thermal treating and forming the second dielectric layer and gate electrode are carried out on the channel region including the recess region and the step region.

In yet further embodiments, methods of forming a gate structure for an integrated circuit memory device include forming a metal oxide dielectric layer on an integrated circuit substrate and thermally treating the substrate including the metal oxide dielectric layer at a temperature over a crystallization temperature of the metal oxide dielectric layer. Ions of germanium (Ge) are injected into the thermally treated first dielectric layer at an ion injection energy of less than about 10000 electron volts (eV) and at an ion projection dose from about 1×10¹⁴/cm² to about 2×10¹⁶/cm² to form a charge storing region in the metal oxide dielectric layer with a tunnel dielectric layer under the charge storing region and a capping dielectric layer above the charge storing region. The substrate including the first dielectric layer and the second dielectric layer is rapid thermal annealed at about 700° C. to about 900° C. for about 5 minutes to about 30 minutes to form a plurality of discrete charge storing nano crystals in the charge storing region and a gate electrode layer is formed on the second dielectric layer. Between injecting ions and rapid thermal annealing, a second dielectric layer may be formed on the metal oxide dielectric layer, The second dielectric layer may be a metal oxide having a thickness of less than about 10 nm.

In other embodiments, gate structures for an integrated circuit device include an integrated circuit substrate and a metal oxide dielectric layer on the substrate. The metal oxide dielectric layer includes a tunnel dielectric layer on the substrate, a charge storing layer including a plurality of discrete nano-crystals of a selected element from group 4 of the periodic table and having a thermal diffusivity of less than about 0.5 centimeters per second (cm²/s) on the tunnel dielectric layer and a capping dielectric layer on the charge storing layer. A gate electrode layer is on the capping dielectric layer. The metal oxide dielectric layer may be a first dielectric layer and the gate structure may further include a second dielectric layer interposed between the capping dielectric layer and the gate electrode layer. The second dielectric layer may be a metal oxide and have a thickness of less than about 10 nm and the first dielectric layer may have a thickness of no more than about 20 nm. The first and second dielectric layers may be an oxide and/or oxynitride of aluminum, hafnium, titanium, zirconium, scandium, yttrium and/or lanthanum.

In further embodiments, the tunnel dielectric layer has a thickness of no more than about 9 nm and the nano crystals have a diameter from about 1 nm to about 7 nm and a spacing between ones of the nano crystals is between about 1 nm and about 7 nm. The charge storing region may include a multi-layer structure of overlapping ones of the discrete charge storing nano crystals.

In some embodiments, the memory cell further includes a common gate on a gate dielectric layer on the substrate and the metal oxide dielectric layer extends along sidewalls of the common gate electrode and on a channel portion of the substrate proximate respective sides of the common gate. The memory cell further includes sidewall gates on the metal oxide dielectric layer proximate the respective sides of the common gate and extending over the channel portion.

In other embodiments, the memory cell further includes a channel region including a recess region and a step region adjacent the recess region extending between a source and a drain region in the substrate. The metal oxide dielectric layer extends along the channel region including the recess region and the step region. The recess region may have a rounded portion.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic cross-sectional view illustrating erase and program operations in a conventional floating gate memory cell.

FIG. 2 is a schematic cross-sectional view illustrating a leakage path for a conventional continuous floating gate memory cell.

FIGS. 3A through 3D are cross-sectional views illustrating methods of forming a gate structure for an integrated circuit device according to some embodiments of the present invention.

FIGS. 4A and 4B are diagrams illustrating heat treatments for forming a charge storing region including discrete charge storing nano crystals according to some embodiments of the present invention.

FIG. 5 is a cross-sectional view illustrating a charge trapping double layer structure according to some embodiments of the present invention.

FIG. 6 is a cross-sectional view illustrating a flash memory device including a gate structure according to some embodiments of the present invention.

FIGS. 7A through 7C are energy band diagrams for a flash memory device according to some embodiments of the present invention.

FIGS. 8 through 11 are cross-sectional views illustrating flash memory devices including gate structures according to further embodiments of the present invention.

FIG. 12A is a capacitance-voltage (C-V) hysteresis curve for a flash memory device according to some embodiments of the present invention.

FIGS. 12B and 12C are capacitance-voltage (C-V) hysteresis curves for a flash memory device without a metal oxide capping layer.

FIGS. 13A through 13E are capacitance-voltage (C-V) hysteresis curves for a flash memory device thermally treated at different temperatures according to some embodiments of the present invention.

FIG. 14 is a schematic cross-sectional view illustrating a leakage path for a discrete charge storing nano crystal floating gate.

FIG. 15 is a diagram illustrating simulated implantation results according to some embodiments of the present invention.

FIG. 16 is a flowchart illustrating operations for forming a gate structure for an integrated circuit device according to some embodiments of the present invention.

FIG. 17 is a cross-sectional view illustrating a charge trapping double layer structure according to other embodiments of the present invention.

FIG. 18 is a cross-sectional view illustrating a charge trapping single layer structure according to further embodiments of the present invention.

FIGS. 19A through 19C are energy band diagrams for a flash memory device according to other embodiments of the present invention.

FIG. 20 is a TEM photograph illustrating a cross-sectional view of a charge trap double layer structure according to some embodiments of the present invention.

FIG. 21 is a capacitance-voltage (C-V) hysteresis curve for a flash memory device according to other embodiments of the present invention.

FIG. 22 is a graphical illustration of leakage current characteristics according to some embodiments of the present invention.

FIGS. 23A and 23B are capacitance-voltage (C-V) hysteresis curves for a flash memory device according to further embodiments of the present invention.

FIG. 24 is a table of cross-sectional views of charge trap structures and methods of forming the same according to some embodiments of the present invention.

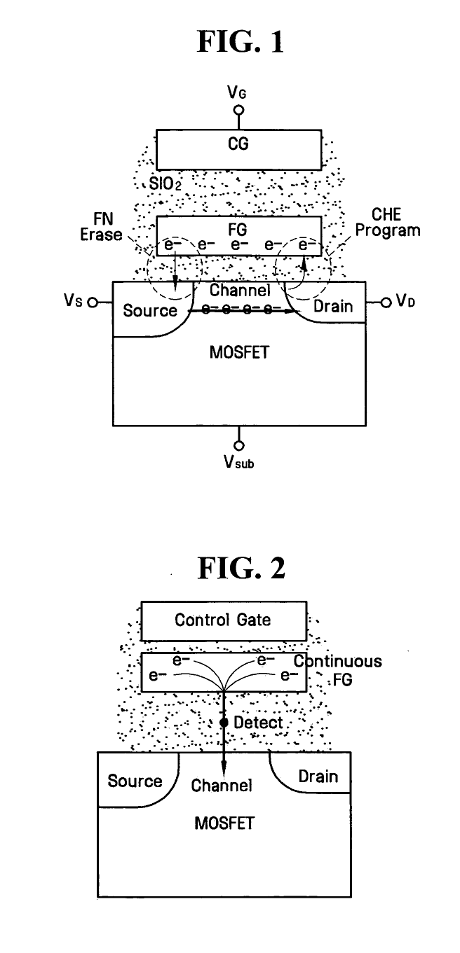

### DETAILED DESCRIPTION OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

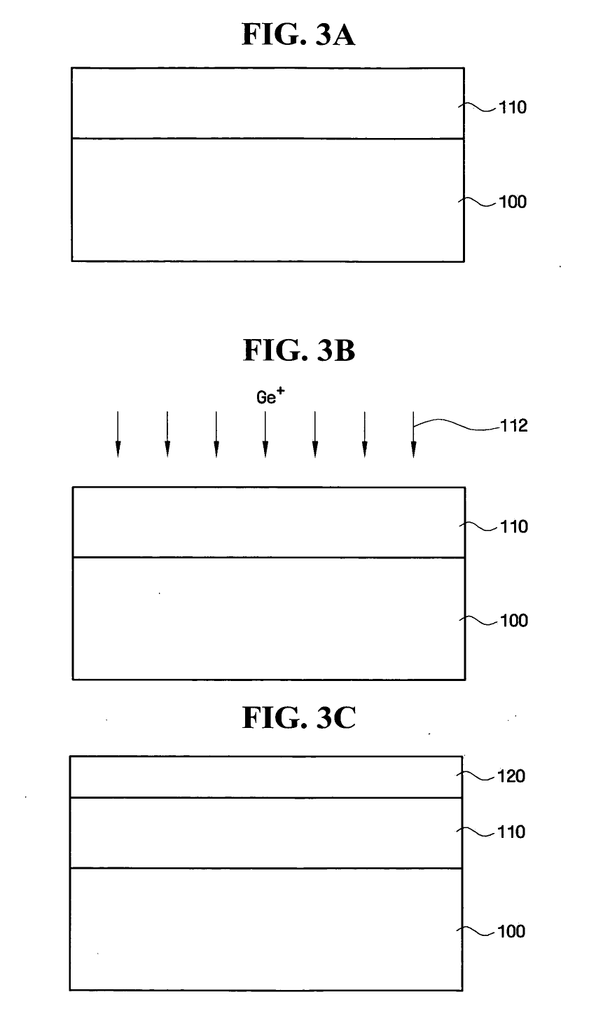

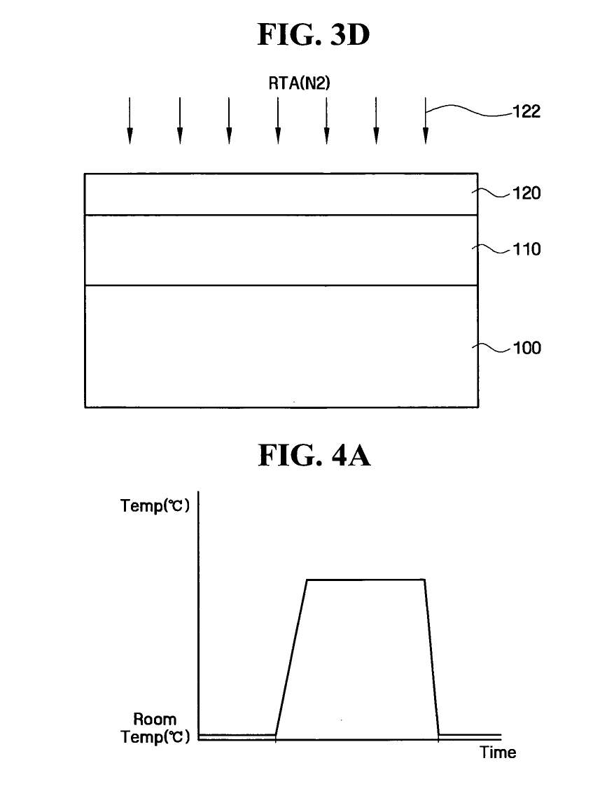

In some embodiments of the present invention, as will now be described with reference to FIGS. 3A through 3D, a gate structure may be provided that is usable in a flash memory device or the like having source and drain regions in a substrate defining a channel region therebetween. A first dielectric layer is formed on the channel region and a second dielectric layer, having an energy band gap of over about 5 electron volts (eV) and a more thin structure than the first dielectric layer, is formed on the first dielectric layer. A plurality of charge storing nano crystals are embedded in the first dielectric layer and a control gate is provided on the second dielectric layer to provide a floating gate structure. The first dielectric layer, after embedding the charge storing nano crystals, may correspond to a tunnel oxide layer under the nano crystals and a portion of the first dielectrode layer above the nano crystals and second dielectric layers may correspond to coupling/capping and blocking layers with a charge storing layer therebetween including a plurality of discrete charge storing nano crystals.

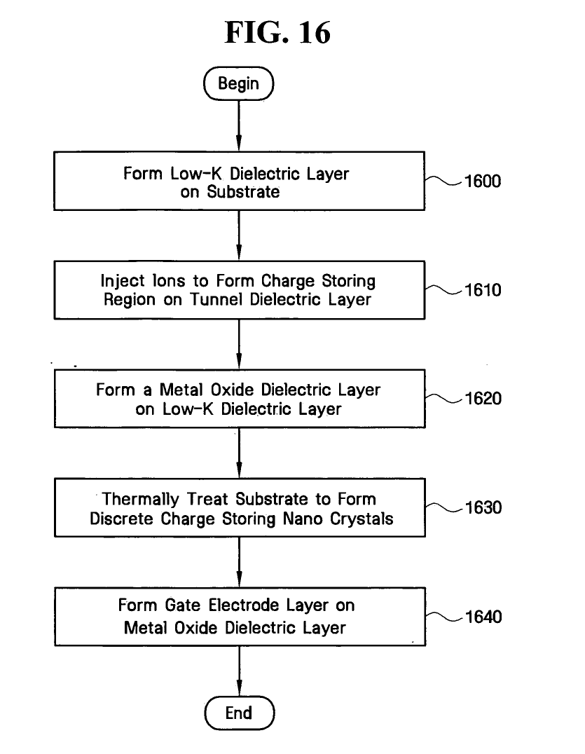

Referring now to the flow chart illustration of FIG. 16 and the cross sectional illustration of FIG. 3A, operations for forming a low-k dielectric layer at Block 1600 are shown in FIG. 3A where a first dielectric layer 110 is shown formed on an integrated circuit (semiconductor) substrate 100. The first dielectric layer 110 may be silicon oxide and may have an energy band gap of over about 5 eV. The thickness of the first dielectric layer 110 may be less than about 17 nanometers (nm) and, in some embodiments may, be about 15 nanometers, which may facilitate formation of a single nano crystal layer in the first dielectric layer 110.

Operations for injecting ions into the first dielectric layer at Block 1610 to form a charge storing region are illustrated in FIG. 3B for some embodiments of the present invention. As seen in FIG. 3B, ions 112 of a selected element from Group IV (group 4) of the periodic table and having a thermal diffusivity of the less than about 0.5 centimeters per second (cm²/s) are injected into the first dielectric layer 110 to form a charge storing region in the first dielectric layer 110 with a tunnel dielectric layer under the charge storing region. For example, as illustrated in FIG. 3B, the ion 112 of a selected element from Group IV may be germanium (Ge).

Table 1 below illustrates various property differences between germanium and silicon ions for injecting into a dielectric layer as described for various embodiments herein. As seen in Table 1, the dielectric constant (k) of germanium is larger than that of silicon and its energy band gap is smaller than that of silicon, which may allow operation of a formed charge storing layer and gate including such a layer at a lower voltage. As further seen in Table 1, the temperature for forming nano crystals is lower for germanium and its thermal diffusivity is smaller so that the nano crystals may more readily be formed at a desired depth location and with lower diffusion variability. Furthermore, as rapid thermal processing (RTP) may proceed at a lower temperature to provide annealing for germanium, a nano crystal signal layer may be more readily formed as heat treatment after ion implantation may result in a less spread out embedded nano crystal structure vertically and in other directions. During thermal processing, the germanium may be more readily prevented from outdiffusion than silicon. As a result, more uniform nano crystal size particles may be provided in a layer as adjacent nano crystals may be less likely to react with each other. Furthermore as the mobility of germanium is larger than that of silicon, it may be possible to operate a device including a gate structure as described herein where germanium is the injected ion at a higher speed than with silicon.

TABLE 1

| | Ge | Si |
|---|---|---|
| Dielectric constant | 16.0 | 11.9 |
| Energy band gap (eV) | 0.66 | 1.12 |
| Nano crystal formation temp. | 700–950 | 950–1100 |
| (° C.) | | |
| Thermal diffusivity (cm2/s) | 0.36 | 0.9 |

| | | | |
|---|---|---|---|
| Mobility | Electron | 3900 | 1500 |
| (cm2/V-s) | Hole | 1900 | 450 |

The conditions for ion injection at Block 1610 may be selected to provide a desired mean injection depth and delta projection range of the implanted layer. More particularly, a desired ion injection energy and ion projection dose may be selected using, for example, Transport of Ions In Matter (TRIM) simulation code.

In some embodiments, a delta projection range of no more than about 7 nanometers (nm) is provided about a selected mean injection depth. A delta ion projection range under 7 nm may allow a thickness of a dielectric layer-135 (FIG. 5) under the layer of discrete nano crystal discrete particles 130_NC (FIG. 5) to be no more than about 6 nm. In some embodiments of the present invention, ions are injected at a selected mean injection depth at Block 1610 with a delta projection range of from about 80 Å to about 120 Å.

In some embodiments of the present invention, the first dielectric layer 110 has a thickness of less than about 17 nm. Injecting ion operations at Block 1610 in some embodiments includes injecting the ions in an ion injection energy of greater than 7,000 eV and no more than about 30,000 eV and at an ion projection dose from about 1×10¹⁴ cm² to about 2×10¹⁶ cm².

Referring now to FIG. 16 and FIG. 3C, a second dielectric (capping) layer 120 is formed on the first dielectric layer 110 (Block 1620). More particularly, the second dielectric layer 120 in some embodiments of the present invention is a metal oxide. In particular embodiments, the second dielectric layer 120 may be an oxide and/or oxynitride of aluminum, hafnium, titanium, zirconium, scandium, yttrium and/or lanthanum. The first dielectric layer 110 may be formed by thermal oxidation on the substrate 100 and the second dielectric layer 120 may be formed by atomic layer deposition (ALD) and/or plasma enhanced chemical vapor deposition (PECVD).

The metal oxide of the second dielectric layer 120 may be over 50 eV in energy band gap and may be a thinner and/or more dense layer than the first dielectric layer 110. The second dielectric layer 120 may operate to limit or block tunneling of electrons passing through the first dielectric layer 110 to a control gate formed on the second dielectric layer 120 during a programming operation. A thickness of the second dielectric layer 120 may be less than about 10 nm in some embodiments of the present invention, which may increase the capacitance of a gate including the second dielectric layer 120 to facilitate higher speed operation. A sampling of materials that may be used to form the second dielectric layer 120 include, for example, aluminum oxide (Al₂O₃), hafnium oxide (HfO₂) and zirconium oxide (ZrO₂), where aluminum oxide has a dielectric constant of 9 and an energy band gap of 8.7 eV, hafnium oxide has a dielectric constant of 25 and an energy band gap 5.7 eV and zirconium oxide has a dielectric constant of 25 and an energy band gap of 7.8 eV.

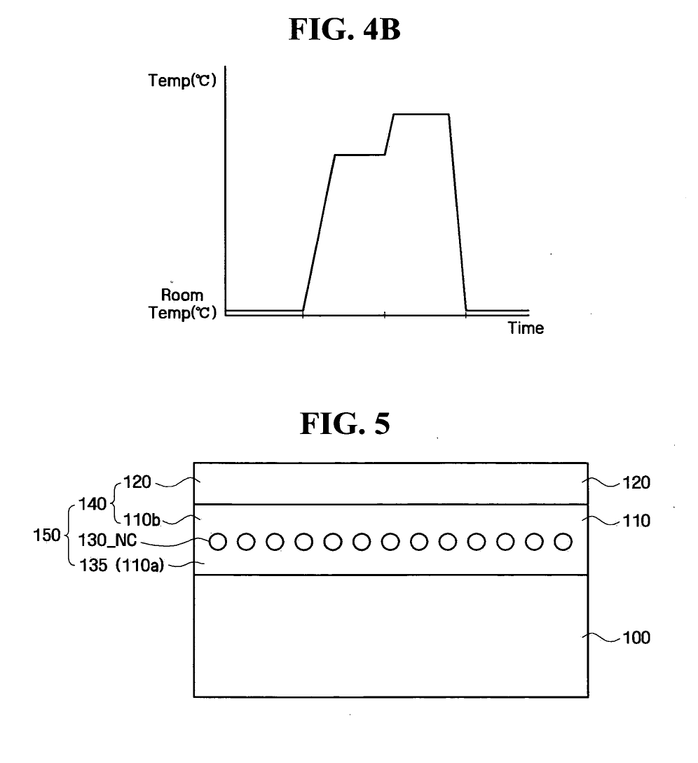

Operations related to thermally treating a substrate including the first 110 and second 120 dielectric layers to form a plurality of discrete charge storing nano crystals in a charge storing region of the first dielectric layer 110 is shown at Block 1620 of FIG. 16, will now be described with reference to FIGS. 3D and 4A-4B. As seen in the schematic illustration of FIG. 3D, in some embodiments of the present invention, rapid thermal annealing 122 is used as a thermal treatment to rapid thermal anneal the first dielectric layer 110. Rapid thermal annealing may be performed, for example, in an atmosphere of nitrogen (N₂) gas.

As shown in FIGS. 4A and 4B, a one step (FIG. 4A) or two step (FIG. 4B) annealing process may be used for operations at Block 1620 of FIG. 16. A single step thermal annealing may be performed at a temperature of about 700° C. to about 900° C. for about 5 minutes to about 30 minutes. In particular embodiments, the one step annealing is performed for 10 minutes. Referring now to FIG. 4B, the first thermal annealing may be under the same temperature conditions as described with reference to FIG. 4A so as to form discrete nano crystals in a charge storing region of the first dielectric layer 110. In some embodiments of the present invention, the nano crystals have a diameter from about 1 nm to about 7 nm and a spacing between ones of the nano crystals may be between about 1 nm and about 7 nm. In some embodiments, a substantially single layer of the nano crystals are formed in the first dielectric layer 110. In further embodiments, a range of diameters of the nano crystals may be between about 3 nm and about 7 nm.

As further shown in FIG. 4B, after formation of the nano crystals, a second annealing may be performed that may increase a compactness of the first dielectric layer 110 and may further cure or remediate the damage caused to the first dielectric layer 110 during ion injection. The second rapid thermal annealing, in some embodiments, may be at a temperature of about 900° C. to about 1050° C. for about 5 minutes to about 30 minutes. The relatively higher temperature of the second annealing may beneficially cure damage to the first dielectric layer 110.

A gate structure for an integrated circuit memory device according to some embodiments of the present invention will now be described with reference to the cross-sectional illustration of FIG. 5. FIG. 5 illustrates a charge trap double layer 150 including the annealed first dielectric layer 110 and the annealed second dielectric layer 120. A plurality of charge storing nano crystals 130_NC are embedded in the annealed first dielectric layer 110. A first dielectric layer region 110a under the nano crystals 130_NC forms a tunnel dielectric layer or tunnel oxide 125 under the charge storing region including the nano crystals 130_NC. The first dielectric layer region 110b above the nano crystals 130_NC and the second dielectric layer 120 correspond to coupling and blocking oxides 140. As used herein, the region 110b of the first dielectric layer 110 may be referred to as a coupling dielectric or oxide layer and the second dielectric layer 120 may be referred to as the blocking dielectric layer or oxide layer.

The tunnel dielectric layer 135, in some embodiments, has a thickness of no more than about 6 nm. The second dielectric layer 120 may have a thickness of less than about 10 nm. The first dielectric layer 110 may be silicon oxide and the second dielectric layer 120 may be a high-k dielectric layer.

When the first dielectric layer 110 is silicon oxide and the second oxide layer is a metal oxide, such as aluminum oxide, hafnium oxide or zirconium oxide, the annealed second dielectric layer 120 may include silicon therein diffused from the first dielectric layer 110 during annealing. The silicon atom content in the second dielectric layer 120 may have a concentration gradient decreased along the surface of the second dielectric layer 120 from the interface between the first 110 and second 120 dielectric layers. Similarly, the second dielectric layer 120 may include diffused ones of the implanted ions from the first dielectric layer 110, such as germanium ions, and the ion atom content in the second dielectric layer 120 may also have a concentration gradient decreased along the surface of the second dielectric layer from the interface between the first 110 and the second 120 dielectric layers. Such diffusion may be bi-directional in that the silicon oxide first dielectric layer 110 may also include aluminum, hafnium, zirconium or other metal from the second dielectric layer 120 that is diffused from the second dielectric layer 120 during annealing. As such, a metal content in the first dielectric layer 110 may have a concentration gradient decreased from the interfaced between the first 110 and second 120 dielectric layers towards the substrate 100.

As illustrated in FIG. 5, in some embodiments, the second dielectric layer 120 is less thick than the first dielectric layer 110. For example, as described at various points above, the second dielectric layer may have a thickness of about 10 nm while the first dielectric layer 110 may have a thickness of less than about 17 nm.

While shown in FIG. 5 as a single layer of discrete nano crystals 130_NC at a single mean injection depth, it will be understood that, in some embodiments of the present invention, a plurality of layers of discrete nano crystals 130_NC may be provided in the charge storing region of the first dielectric layer 110. In such embodiments, the multilayer structure may be provided by injecting ions of a selected element at a first ion injection energy to form a first charge storing layer on the tunnel dielectric layer 135 and injecting ions of a selected element at a second ion injection energy less than the first ion injection energy, to form a second charge storing layer at a different depth than the first charge storing layer, with the region therebetween substantially free of implanted ions. It will be understood that, as used herein, a multi-layer structure being substantially free of implanted ions allows for implantation of some ions based on the selected mean injection depths and the delta projection range characteristics of the ion injection processes. It will be further understood that, while described above with reference to two layers, ions may be injected at a plurality of different height locations relative to the substrate 100 in the first dielectric layer 110 and a thermal treatment process of the substrate 100 and first dielectric layer 110 and second dielectric layer 120 may provide a multi-layer structure of overlapping ones of the discrete charge storing nano crystals.

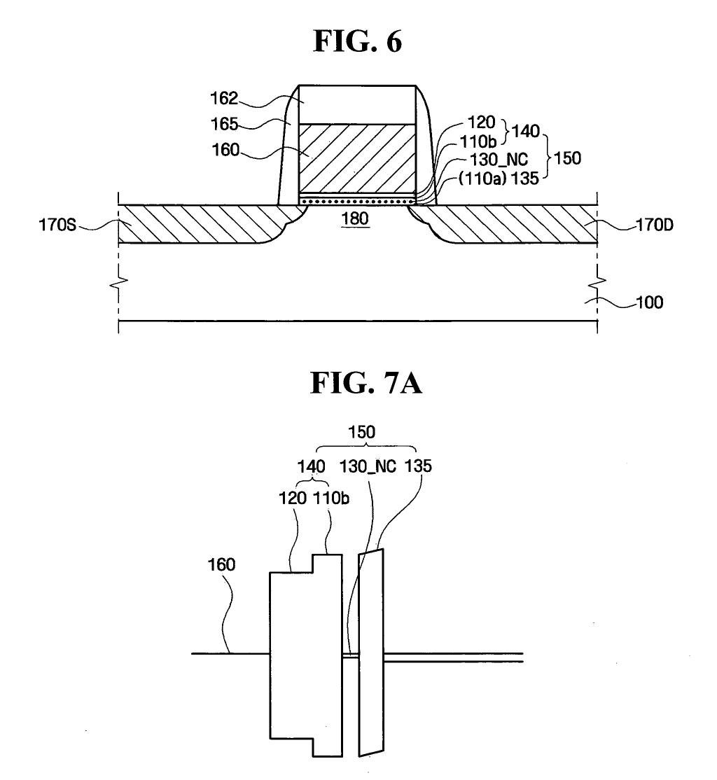

A flash memory device including a gate structure according to some embodiments of the present invention will now be described with reference to the cross sectional illustration of FIG. 6. As seen in FIG. 6, the flash memory device includes a substrate 100 having a source region 170S and a drain region 170D formed therein with a channel region 180 extending between the source 170S and drain 170D regions.

A charge trapping double layer 150 is formed on the channel region 180. The charge trap double layer 150 as illustrated includes a tunnel oxide layer 135 defined by a lower region 110a of the first dielectric layer 110. A thickness of the tunnel oxide layer 135 may be under 6 nm and, in some embodiments, may be from about 4.5 nm to about 5.5 nm. A thickness of the tunnel oxide layer 135 may be selected so as to be thin enough to provide for tunneling of electrons when a program voltage is applied to the flash memory device.

The discrete charged nano crystals 130_NC have a diameter of about 1 nm to about 15 nm in various embodiments and, in some embodiments, have a diameter between about 3 nm and about 7 nm. The nano crystals 130_NC may be dot type and a space between the nano crystals 130_NC may be between about 3 nm and about 7 nm. A distance between the nano crystals 130_NC may be selected to limit or even prevent lateral diffusion of charges. The illustrated charge trapping double layer 150 further includes the coupling and blocking oxide layer 140, including the region 110b of the first dielectric layer 110 and the second dielectric layer 120.

A gate electrode layer is formed on the substrate to define a control gate 160 on the second dielectric layer 120. The control gate 160 may be metal, doped polysilicon and/or the like. The control gate 160, while shown as a single layer structure in the embodiments of FIG. 6, may also be multi-layer structure.

Also shown in the flash memory device illustrated in FIG. 6 are sidewall spacer(s) 165 and a further capping layer 162. The sidewall spacer 165 is shown on each side of the control gate 160 and may be formed as a silicon oxide liner or the like.

While described with reference to FIG. 6 as a flash memory device, it will be understood that various embodiments of the present invention may provide a gate structure that may be used in a non-volatile memory device and/or dynamic random access memory device (DRAM). However, the embodiments described herein are described with reference to a floating gate structure, such as found on a flash memory device.

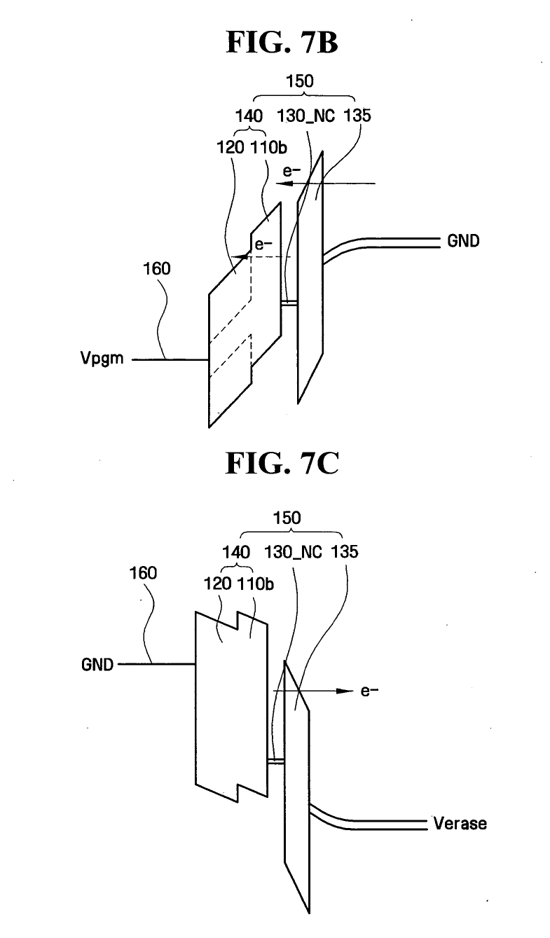

Operation of the memory device of FIG. 6 will now be described further for some embodiments of the present invention with reference to the energy band diagrams of FIGS. 7A through 7C. FIG. 7A illustrates an initial state energy band diagram. In particular, FIG. 7A illustrates an embodiment in which the energy band gap for the first dielectric layer 110 is 9 eV and the first dielectric layer is silicon oxide. The energy band gap for the second dielectric layer 120 is 8.7 eV and the second dielectric layer is aluminum oxide. The energy band gap of the discrete nano crystals for germanium nano crystals 130_NC is 0.66 eV. The control gate 160 may be aluminum.

For the illustration in FIG. 7A, the tunnel oxide layer 135 may be silicon oxide having a thickness of about 6 nm. A mean diameter of the germanium nano crystals 130_NC may be 4 nm and a single layer of the nano crystals 130_NC may be provided. The coupling and blocking layer 140 as shown in FIG. 7A is for a silicon oxide region 10b of the first dielectric layer having a thickness of about 7 nm and for an aluminum oxide second dielectric layer 120 having a thickness of about 10 nm.

Erase and program operations for the exemplary energy band diagrams shown in FIG. 7A will now be described with reference to the illustrative energy band diagrams of FIGS. 7B and 7C respectively.

Referring to FIG. 7C, an erase operation state of the device shown in FIG. 6 is illustrated. In particular, a ground voltage is shown applied to the control gate 160 and a negative erasing voltage (Vₑᵣₐₛₑ) is shown applied to the substrate 100. As such, charge stored on the discrete charge storing nano crystals 130_NC is radiated towards the substrate 100 by FN tunneling and/or hot carrier injection as illustrated by the solid arrow line in FIG. 7C.

Referring now to FIG. 7B, a program operation state of the device of FIG. 6 will be described. As shown in FIG. 7B, a positive voltage (V_{pgm}) is applied to the control gate 160 and a ground voltage (GND) is applied to the substrate 100. As such, an electron traveling from the channel region 180 is trapped in the charge storing region including the discrete charge storing germanium nano crystals 130_NC after passing through the tunnel oxide layer 135 by FN tunneling. It will be understood, however, that when a positive programming voltage (V_{pgm}) is applied to the control gate 160 and a high voltage similar to V_{pgm} is applied to the source region 170S and the ground voltage GND is applied to the drain region 170D, hot carrier electrons generated adjacent to the source region 170S can be injected and trapped by the nano crystals 130_NC after passing through the tunnel oxide layer 135 as shown by the solid arrow line in FIG. 7B. In other words, FN tunneling and/or hot carrier electron programming may be used in some embodiments of the present invention.

If a coupling ratio of the voltage applied to the control gate 160 is high, a higher voltage may be transferred to the nano crystals 130_NC. This may induce an effective injection of the FN tunneling and/or the hot carrier electron flow. In other words, it may be possible to make the non-volatile memory device operate quickly using the second dielectric film 120 made of high dielectric constant material such as a metal oxide.

As the energy band gap of the first dielectric film region 110b in some embodiments is about 8 to about 9 electron volts, if the energy band gap of the second dielectric film 120 is under 5 eV (see the dotted line in FIG. 7B), the trap charge in the nano crystals 130_NC may be further tunneled towards the control gate 160. As a result, the second dielectric film 120 in some embodiments of the present invention has an energy band gap of over 5 electron volts to provide performance in blocking tunneling of the electron charge from the nano crystals 130_NC towards the control gate 160.

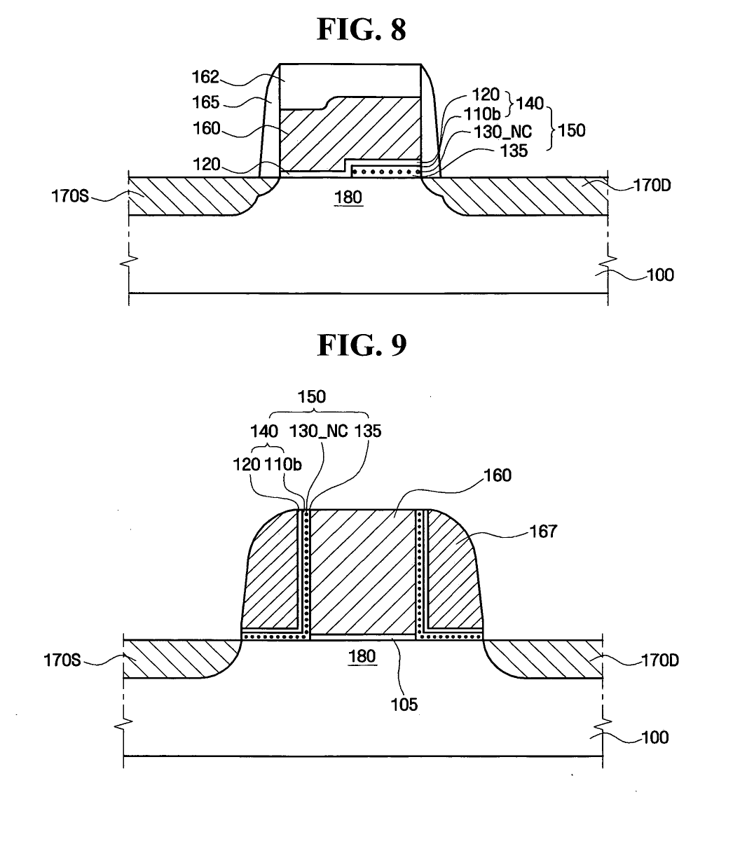

Further embodiments of integrated circuit memory devices will now be described with reference to the cross sectional illustrations of FIGS. 8-11. Referring first to the embodiments illustrated in FIG. 8, a charge trap double layer 150 is illustrated formed on a portion of the channel region 180. The second dielectric layer 120 is formed as a gate dielectric layer on the remaining portion of the channel region 180. The control gate 160 is formed on the second dielectric layer 120. In other words, the charge trap double layer 150 in the embodiments illustrated in FIG. 8 does not extend fully across the channel region 180 as described with reference to the embodiments of FIG. 6. The configuration of embodiments illustrated in FIG. 8 may provide a reduced consumption of electricity of the memory device during operation and may, thereby, enhance programming and erasing efficiencies for the memory device.

The gate structure illustrated in FIG. 8 may be formed substantially as described previously herein. In particular, after the selected size of the first dielectric 110 is formed on the substrate 100, ions to be used for generating discrete charge storing nano crystals are injected into the formed first dielectric layer 110. The second dielectric layer 120 is formed covering the first dielectric layer 110 and on the substrate 100. The nano crystals 130_NC may then be formed in the first dielectric layer 110 by a thermal treatment, such as a rapid thermal annealing process as described previously.

A flash memory device according to further embodiments of the present invention will now be described with reference to FIG. 9. As shown in the cross sectional view of FIG. 9, the charge trap double layer 150 is formed between a sidewall gate 167 and the channel region 180. The charge trapped double layer 150 is also shown extending between the sidewall gate 167 and the main control gate 160. A gate oxide layer 105 is shown formed between the control gate 160 and the substrate 100 in the channel region 180. After forming a gate oxide layer 105 and the control gate 160, the charge trap double layer 150 is formed on the resultant substrate 100. A conductive film for a sidewall gate may then be deposited. The sidewall gate 167 may be formed from the deposited conductive film, for example, by an etch-back process. The structure illustrated in FIG. 9 may, thus, provide a floating gate structure for a multi-bit memory cell.

The embodiments illustrated in FIG. 9 differ from the embodiments described with reference to FIG. 6 and FIG. 8 in that a common gate 160 is formed on a gate dielectric layer 105 and the substrate 100 before forming the first dielectric layer 110. Operations related to implanting ions and thermally treating the first dielectric layer 110 and the second dielectric layer 120 are further carried out on sidewalls of the common gate electrode 160 and on a portion of the channel region 180 of the substrate 100 proximate respective sides of the common gate 160. Sidewall gates 167 are formed on the second dielectric layer 120 proximate the respective sides of the common gate 160 and extending over a portion of the channel region 180 including the charge trap double layer 150.

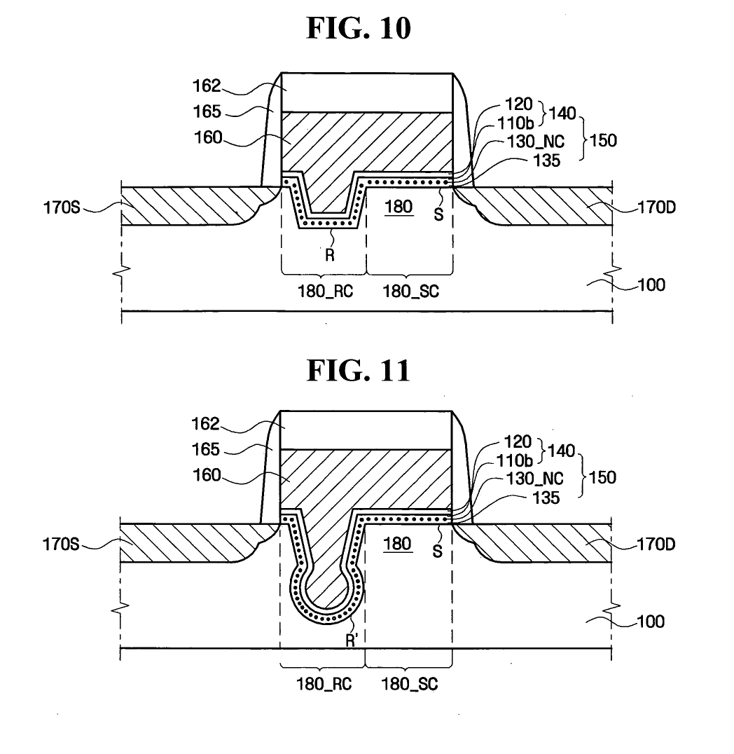

A memory cell structure according to further embodiments of the present invention will now be described with reference to FIG. 10. For the embodiments illustrated in FIG. 10, the channel region 180 includes a recess region 180_RC and step region 180_SC adjacent the recess region 180_RC, which regions extend between the source region 170S and the drain region 170D in the substrate 100. The charge trap double layer 150 is shown formed on the channel region 180 including the recess region 180_RC and the step region 180_SC. Also shown in the embodiments of FIG. 10 are sidewall spacer 165 and the further capping layer 162.

The memory cell structure illustrated in the embodiments of FIG. 11 is similar to that described with reference to FIG. 10. The embodiments illustrated in FIG. 11 differ from those of FIG. 10 in that the recess region 180_RC includes a rounded portion. The embodiments illustrated in FIGS. 10 and 11, like those in FIG. 9, may be suitable for use as a multi-bit storage cell of a memory device.

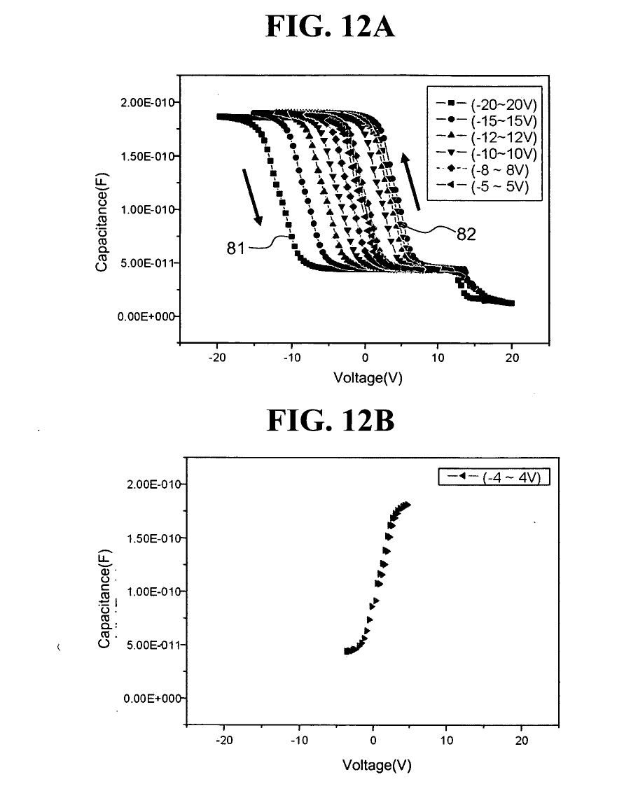

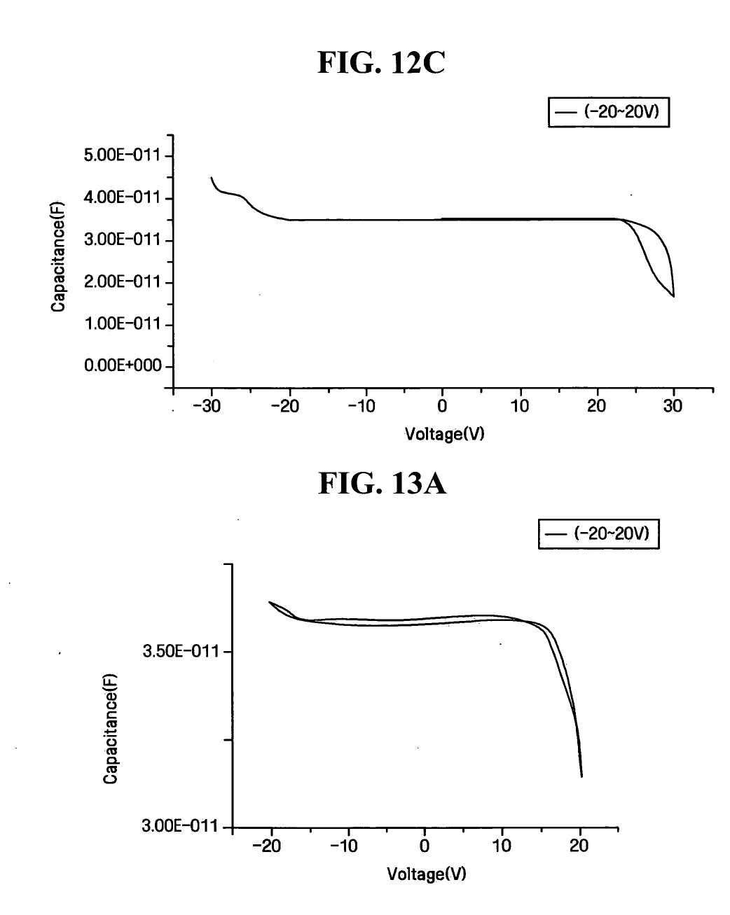

Operation of some embodiments of the present invention will now be further described with reference to the capacitance-voltage (C-V) hysteresis curves shown in FIGS. 12A through 12C. FIG. 12A illustrates operation characteristics for embodiments of the present invention when the selected element from group 4 of the periodic table used for the ions injected into the first dielectric layer 110 is germanium. More particularly, for the simulation results in FIG. 12A, germanium ions are injected at an ion projection dose of about 2×10¹⁶/cm² at an ion injection energy of about 30 keV into a silicon oxide first dielectric layer 110 having a thickness of about 17 nm. The first dielectric layer 110 is grown by a thermal oxidation process on p-type substrate 100. An aluminum oxide second dielectric layer 120 is formed having a thickness of about 10 nm. Discrete charge storing nano crystals 130_NC are formed by rapid thermal annealing (RTA) in a nitrogen atmosphere at a temperature of about 800° C. for about 10 minutes. An aluminum control gate is formed on the second dielectric layer 120.

As illustrated in FIG. 12A, using embodiments of the present invention having a charge trap double layer 150, the capacitance moves in the direction 81 by a voltage sweep from a negative applied voltage to a positive applied voltage. In the reverse direction, the capacitance moves in the direction 82 by a voltage sweep from a positive applied voltage to a negative applied voltage. In other words, the embodiments illustrated in FIG. 12A have a desirable counter clock-wise hysteresis. The capacitance variation in the direction 81 represents that the interface between the silicon oxide layer 110 and the p-type substrate 100 may be changed to the inversion state through the cumulation of electrons. When the p-type substrate 100 surface reaches the inversion state, the electrons may be trapped in the germanium nano crystals 130_NC in the charge storing region of the first dielectric layer 110. On the other hand, the capacitance curve in the direction 82 has a positive flat band voltage shift due to the electron trapping in the discrete charge storing nano crystals 130_NC.

As further illustrated in the CV curve of FIG. 12A as the range of applied voltage increases, the hysteresis width increases by increasing the positive flat-band voltage shift. As such, as the applied voltage increases, the number of electrons trapped in the germanium nano crystals 130_NC may increase to accumulate more charge. In other words, better charge trapping may occur during programming to improve device operation and performance. As such, as illustrated in FIG. 12A, some embodiments of the present invention provide a counterclockwise hysteresis characteristic and a hysteresis width favorable to operation of a memory device.

For the C-V hysteresis curve illustrated in FIG. 12B, the second dielectric layer 120 is a silicon nitride layer having a thickness of about 30 nm, as contrasted with the 10 nm thickness aluminum oxide used for the embodiments illustrated in FIG. 12A. To the extent hysteresis is shown FIG. 12B, a clockwise hysteresis characteristic is present when a silicon nitride having a 5 eV energy band gap is used as the second dielectric layer 120.

For the C-V hysteresis curve shown in FIG. 12C, a silicon oxide layer having a thickness of about 100 nm is used the second dielectric layer 120 instead of the aluminum oxide shown in FIG. 12A. The hysteresis curve shown in FIG. 12C may not have a normal characteristic when silicon oxide is used as the second dielectric layer 120.

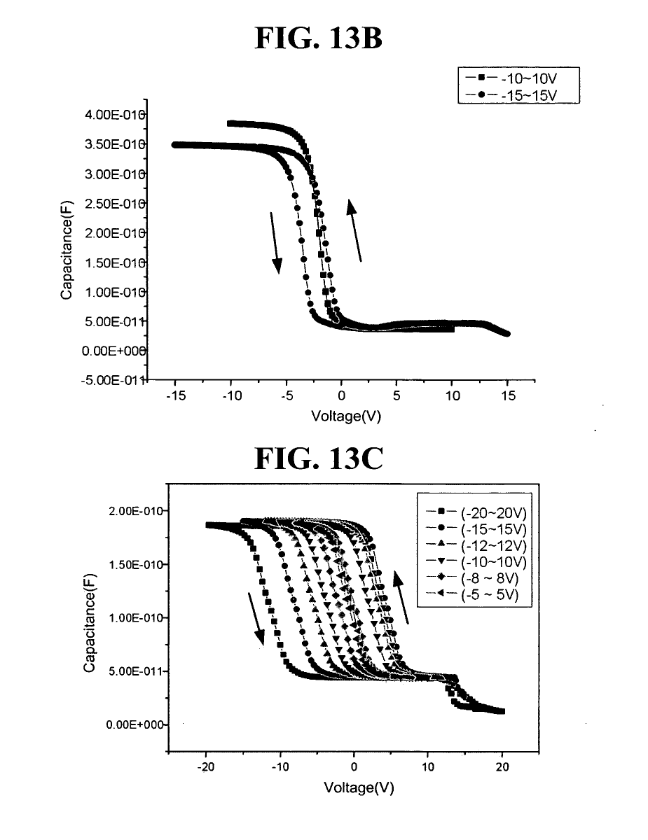

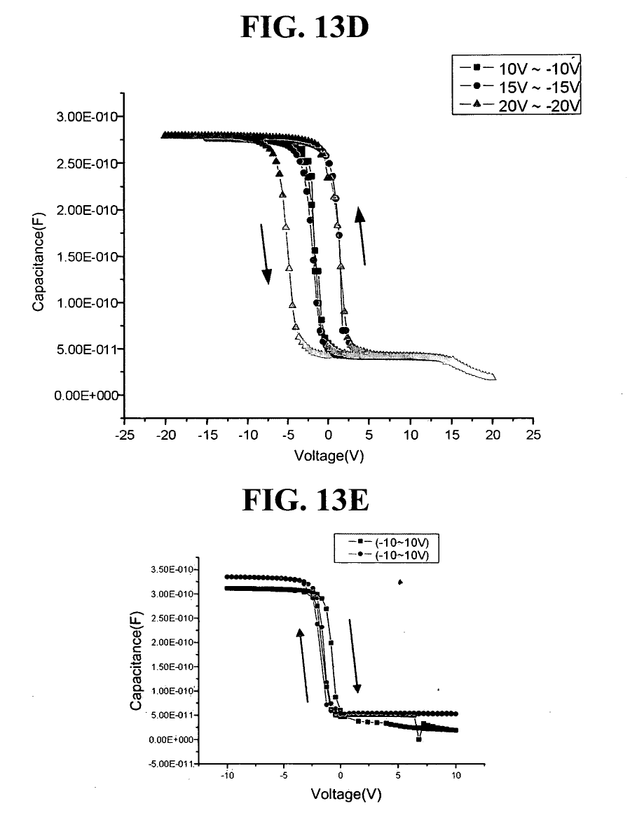

FIGS. 13A through 13E illustrate C-V hysteresis curves for various annealing temperatures used in forming the discrete charge storing nano crystals 130_NC in the charge storing region of the first dielectric layer 110. The curves illustrated in FIGS. 13A through 13E are based on a structure including germanium ions injected at an ion projection dose of about 2×10¹⁶/cm² and an ion injection energy of about 7 keV into a silicon oxide first dielectric layer 110 grown by a thermal oxidization process on the p-type substrate 100 to a thickness of about 17 nm. Furthermore, an aluminum oxide second dielectric layer 120 having a thickness of about 10 nm is formed on the first dielectric layer 110.

A thermal treatment to form the discrete charge storing nano-crystals 130_NC is performed by rapid thermal annealing in a nitrogen atmosphere for a time of about 10 minutes at a different temperatures in each of the respective thickness. More particularly, FIG. 13A corresponds to a temperature of about 600° C., FIG. 13B corresponds to a temperature of about 700° C., FIG. 13C corresponds to a temperature of about 800° C., FIG. 13D corresponds to a temperature of about 900° C. and FIG. 13E corresponds to a temperature of about 950° C. An aluminum control gate is then formed on the resulting charge trap double layer 150.

For the illustrated C-V hysteresis curve at a temperature of 600° C. in FIG. 13A, a normal hysteresis characteristic is not provided. In the case of annealing at a temperature of about 950° C. is illustrated in FIG. 13E, an unstable clockwise hysteresis characteristic appears.

In contrast, for annealing at temperatures of 700° C., 800° C. and 900° C., as illustrated in FIGS. 13B through 13D, a desirable counterclockwise hysteresis characteristic is provided for a memory device. In particular, the C-V hysteresis curves shown for the annealing temperature of 800° C. in FIG. 13C may provide a particularly desirable memory hysteresis characteristic for some memory devices formed in embodiments of the present invention.

Further examples of hysteresis characteristics according to embodiments of the present invention are illustrated in Table 2 below. In particular, Table 2 provides examples of hysteresis characteristics at various germanium ion injection energies and various annealing temperatures for a device including an aluminum oxide second dielectric layer 120 at thicknesses of 10 nm and 20 nm respectively. In Table 2, a clockwise hysteresis characteristic is indicated by a CW and a counterclockwise hysteresis is indicated by CCW. Note that, as shown in the examples of Table 2, for an aluminum oxide thickness of under about 10 nm, and germanium ion injection energies of 7 to 30 keV at annealing temperatures of 700° C. to 900° C. for 10 minutes or less, favorable device characteristics are shown.

TABLE 2

| | Temp./Time | | | | |
|---|---|---|---|---|---|
| | (° C./Min) | 1 KeV | 3 KeV | 5 KeV | 7 KeV/30 kEv |
| Al2O3 | 700/10 | C.W | C.W | C.W | C.C.W |
| (10 nm) | 800/10 | C.W | C.W | C.W | C.C.W |
| | 800/30 | C.W | C.W | C.W | C.W |
| | 900/10 | C.W | C.W | C.W | C.C.W |
| Al2O3 | 800/10 | C.W | C.W | C.W | C.W |
| (20 nm) | 800/30 | C.W | C.W | C.W | C.W |
| | 900/10 | C.W | C.W | C.W | C.W |

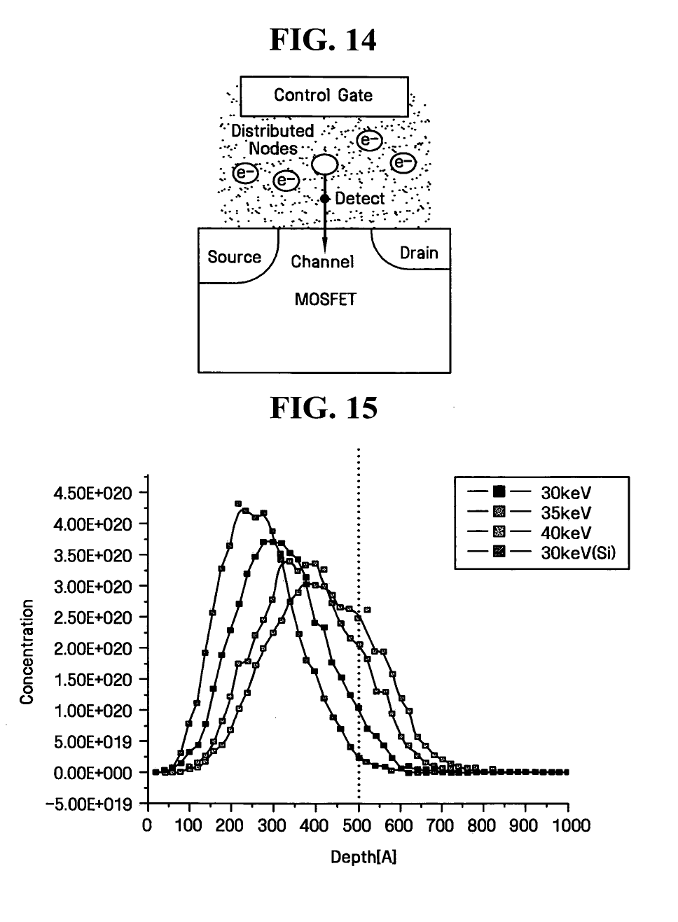

It will be understood that some embodiments of the present invention provide discrete charge storing nano crystals 130_NC. As such, as illustrated in FIG. 14, a single leakage path of the trapped charge electrons may be provided, as contrasted with the leakage characteristics of the continuous floating gate structure described above with reference to FIG. 2. In other words, leakage paths caused by defects or the like in the first dielectric layer 110 may cause only a limited amount of charge leakage allowing continued operation of the floating gate formed by the discrete charge storing nano crystals 130_NC.

As further described generally above for various embodiments of the present invention, process simplification may be provided by the methods described herein. Furthermore, ion diffusion may be limited or even prevented by a fine capping layer structure of the second dielectric layer 120. Annealing and stable nano crystal formation may be provided while still curing damage caused to the oxide layer during ion injection. For example, the two step annealing process described with reference to FIG. 4B above may be particularly beneficial in repairing such damage cause to the oxide layer 110 during ion injection. In addition, in some embodiments, low power and high speed operation of the resulting memory device including the charge trapping double layer 150 may be provided due to a blocking and coupling dielectric layer 140 having a high dielectric constant. Enhanced hysteresis characteristics on a C-V hysteresis curve may also be provided as described herein.

Germanium ion implantation simulation results are illustrated in FIG. 15. More particularly, FIG. 15 illustrates simulation results for germanium ion implantation at an angle of 7° C. into a silicon oxide target layer having a thickness of 500 Å at the respective ion injection energies of 20 keV, 30 keV, 35 keV and 40 keV. The simulation results illustrated in FIG. 15 show a mean injection depth (Rₚ) of about 350 to about 400 Å with a delta projection range of about 80 Å to about 120 Å. The associated mean injection depth and delta projection range for the respective ion injection energies are shown in Table 3 below.

TABLE 3

| | | Delta |
|---|---|---|
| Energy | Rp | Rp |
| 30 keV | 331.8 Å | 103.2 Å |
| 35 keV | 370.6 Å | 112.9 Å |
| 40 keV | 408.6 Å | 120.2 Å |
| 30 keV | 260.9 Å | 91.9 Å |
| (Si) | | |

About Rp: 350–400 A
Delta Rp: 80–120 A

Referring again to the flow chart illustration of FIG. 16, a method of forming a gate structure for an integrated circuit memory device will now be summarized. Operations begin by forming a low-k dielectric layer, such as a silicon oxide layer, as a first dielectric layer on an integrated circuit substrate (Block 1600). Ions of a selected element of group 4 of the periodic table, such as germanium, are injected into the first dielectric layer, for example, at an ion injection energy of greater than 7000 eV and an ion projection dose from about 1×10¹⁴/cm² to about 2×10¹⁶/cm² to form a charge storing region in the first dielectric layer with a tunnel dielectric layer of about no more than about 6 nm under the charge storing region and a capping dielectric layer above the charge storing region (Block 1610). A metal oxide second dielectric layer is formed on the first dielectric layer to a thickness, for example, of less than about 10 nm (Block 1620). The substrate with the first and second dielectric layers therein is thermally treated, for example, by rapid thermal annealing at a temperature of about 700° C. to about 900° C. for about 5 minutes to about 30 minutes to form a plurality of discrete charge storing nano crystals in the charge storing region (Block 1630). A gate electrode layer is formed on the second dielectric layer (Block 1640).

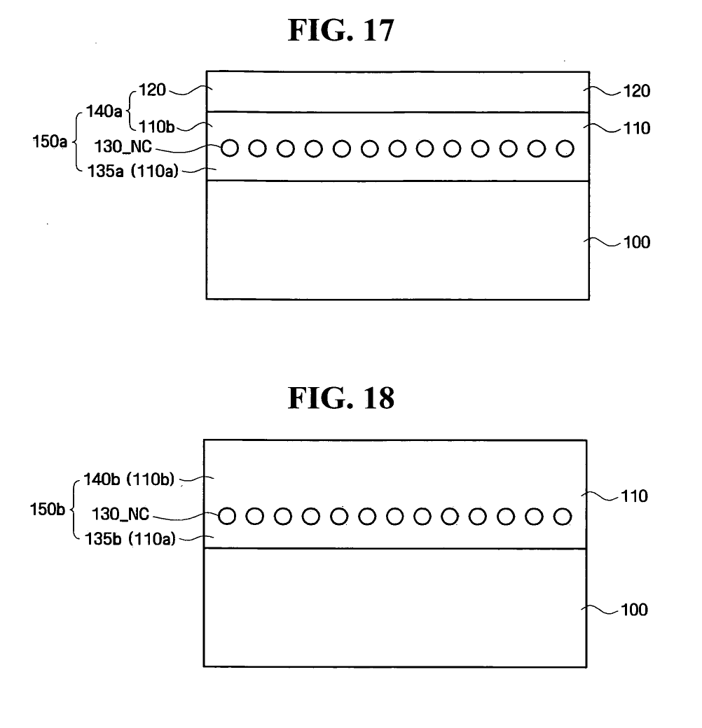

Further embodiments of the present invention will now be described with reference to FIGS. 17 and 18. Like numbered items in FIGS. 17 and 18 generally correspond to those described with reference to FIGS. 3A through 3D and FIG. 5 except as will be described herein. The embodiments of FIG. 17 and FIG. 18 illustrate, respectively, charge trap double layer and single layer structures that may be suitably used in a non-volatile memory device or dynamic random access memory (DRAM), such as a flash memory, device as part of a gate structure. The memory device may include further structures such as described with reference to FIG. 6 above.

Some of the embodiments illustrated and described with reference to FIGS. 17 and 18 may differ from those described previously in that the ions may be injected into a metal oxide layer (or a high-K dielectric layer) formed on a channel region that may have a more compact structure than a silicon oxide such as described previously. As will be further described herein, the first dielectric layer 110 in the substrate 100 may have an energy band gap of over 5 eV and a dielectric constant of over 7 along with a more compact structure than silicon oxide, which may reduce or minimize diffusion of nano crystals formed from injected ions in the vertical and/or horizontal direction within the relatively thin first dielectric layer 110.

The embodiments illustrated in FIG. 17 include a high dielectric constant charge trap double layer structure 150a. The gate structure illustrated in FIG. 17 may be formed, in some embodiments, by forming the first dielectric layer 110 as a metal oxide dielectric layer 110 on the integrated circuit substrate 100. As with previously described embodiments, ions of a selected element from group 4 of the periodic table and having a thermal diffusivity of less than about 0.5 centimeters per second (cm²/s) are injected into the dielectric layer 110 to form a charge storing region in the dielectric layer with a tunnel dielectric layer under the charge storing region and a capping dielectric layer above the charge storing region. As more particularly shown in FIG. 17, a lower region 110a of the dielectric layer 110 corresponds to a tunnel dielectric layer 135a while an upper region 110b of the dielectric layer 110 corresponds to a capping dielectric layer. In the embodiments of FIG. 17, a second dielectric layer 120 is deposited on the first dielectric layer 110 as a blocking dielectric layer. The region 110b, in combination with the second dielectric layer 120 in the embodiments of FIG. 17, corresponds to a coupling and blocking oxide layer 140a.

The substrate 100 including the metal oxide dielectric layer 110 with the ions injected therein is thermally treated to form a plurality of discrete charge storing nano crystals 130_NC in the charge storing region of the dielectric layer 110. A gate electrode 160 (FIG. 6) may be formed on the second dielectric layer 120 to form a gate structure for the embodiments of FIG. 17.

In some embodiments of the present invention, the metal oxide dielectric layer 110 comprises an oxide and/or oxynitride of aluminum, hafnium, titanium, zirconium, scandium, yttrium and/or lanthanum having a dielectric constant of over 7. In some embodiments, the metal oxide dielectric layer 110 comprises aluminum oxide (Al₂O₃) having a dielectric constant of 9 and an energy band gap of 8.7 eV. In other embodiments, the metal oxide dielectric layer 110 comprises hafnium oxide (HfO₂) having a dielectric constant of 25 and an energy band gap of 7.8 eV. In yet further embodiments, the metal oxide dielectric layer 110 comprises zirconium oxide (ZrO₂) having a dielectric constant of 25 and an energy band gap of 7.8 eV. A thickness of the metal oxide dielectric layer 110 may be under about 30 nanometers (nm) and in some embodiments, under about 20 nm.

The ion injected into the metal oxide dielectric layer 110 to form the discrete charge storing nano crystals 130_NC may be germanium and the ion dose may be under 1×10¹⁶/cm² in some embodiments and may be from about 1×10¹⁴/cm² to about 2×10¹⁶/cm² in some embodiments of the present invention. The ions may be injected at an injection energy of the less than about 10,000 eV. A resulting thickness of the tunnel oxide layer 135a may be less than about 9 nm. In some embodiments, an injection energy of greater than 5000 eV may be used for injecting germanium ions into the metal oxide dielectric layer 110.

Before performing ion injection into the metal oxide dielectric layer 110, the ion injection energy and ion projection dose may be adjusted based on a thickness of the metal oxide dielectric layer 110 and/or a desired thickness of the tunnel oxide layer 135a under the embedded nano crystals 130_NC. The ion injection energy and dose may be, for example, determined using transport of ions in matter (TRIM) simulation code.

The second dielectric layer 120 may be a metal oxide and may be a material having a high dielectric constant of over at least about 4 to increase the capacitance characteristic thereof, which may aid in high speed operation and large charge storage capacity of a resultant memory device including the gate structure illustrated in FIG. 17. The second dielectric layer 120 may have a thickness of less than about 10 nm, which may help to maximize a capacitance for high speed operation of a memory device including the illustrated structure. In some embodiments, the second dielectric layer 120 may be an oxide and/or oxynitride of aluminum, hafnium, titanium, zirconium, scandium, yttrium and/or lanthanum. For example, the second dielectric layer 120 may be aluminum oxide, hafnium oxide, zirconium oxide and may be the same material as the first dielectric layer 110. In other embodiments, the second dielectric layer 120 may a silicon nitride layer.

The second dielectric layer 120 may limit or even prevent the implanted ions from out diffusing from the first dielectric layer 110 during a thermal treatment process used to form the discrete nano crystals 130_NC in a desired position in the first dielectric layer 110. Thus, the second dielectric layer 120 may operate as a blocking layer and, in combination with the upper capping portion 110b of the first dielectric layer 110, provide the capping and blocking layer 140a.

As noted above, the first and second dielectric layers 110 and 120 may be the same high dielectric constant material. In such embodiments, the matched material selection may facilitate or enable a high speed operation or larger capacity of a resultant memory device utilizing the gate structure of FIG. 17 and/or simplify a fabrication process associated with forming the structure shown in FIG. 17. The second dielectric layer 120 may be formed using, for example, atomic layer deposition (ALD) and/or plasma enhanced chemical vapor deposition (ECVD).

Referring now to the cross-sectional illustration of FIG. 18, a charge trap single layer structure 150b according to some embodiments of the present invention will now be described. For the embodiments of FIG. 18, the metal oxide first dielectric layer 110 is deposited on the substrate 100 and has, in some embodiments, an energy band gap of over 5 eV and dielectric constant of over 7 and, as described previously, a more compact structure than generally provided with the silicon oxide structure discussed with reference to FIGS. 3A through 3D and FIG. 5. In charge trap single layer structure 150b of FIG. 18, the first dielectric layer 110 includes a lower portion 110a proximate the substrate 100 that defines the tunnel oxide layer 135b and an upper portion 110b defining the coupling and blocking oxide layer 140b. The nano crystals 130_NC may be embedded in the layer 110 at a distance of about 9 nm from the surface of the substrate 100 to provide a tunnel oxide layer 135b of less than about 9 nm. Thus, the structure of FIG. 18 differs from FIG. 17 in that the second dielectric layer 120 is not provided and the upper portion 110b of the first dielectric layer 110 provides the coupling and blocking oxide layer 140b. A thicker first dielectric layer 110 may be provided for the embodiments of FIG. 18 than those of FIG. 17. A selected ion injection energy for the single layer structure of FIG. 18 may be under about 10,000 eV and, in some embodiments, may be greater than about 7 keV and less than about 10 keV. For the structure of FIG. 17, in some embodiments, the injection energy of the ions may be greater than about 5,000 eV and less than about 10 keV.

As noted above, discrete charge storing nano crystals 130_NC for the embodiments of FIG. 17 and of FIG. 18 may be formed by thermally treating the substrate 100 including the dielectric layer 110 after injection of ions. As previously discussed with reference to FIGS. 4A and 4B, the thermal treating process may be a rapid thermal annealing process performed at a temperature of about 700° C. to about 900° for about 5 minutes to about 30 minutes. The rapid thermal annealing for the embodiments of FIG. 17 may be performed after formation of the second dielectric layer 120.

For some embodiments of one step annealing as illustrated in FIG. 4A, rapid thermal annealing may be carried out at about 700° C. to about 950° C. for about 10 to about 30 minutes. In two step annealing as illustrated in FIG. 5B, the first anneal may be at about 700° C. to about 900° C. for about 5 to about 30 minutes followed by a second anneal at about 900° C. to about 1050° C. for about 5 to about 30 minutes. The one step anneal of FIG. 4A or the first anneal of FIG. 4B may proceed at a temperature selected to reduce or minimize out diffusion of injected ions in the dielectric layer 110 and to crystallize the ions to the form discrete charge storing nano crystals 130_NC. Thermal treatment may proceed in a nitrogen gas atmosphere.

The second, higher temperature annealing step illustrated in FIG. 4B may provide a more dense (compact) first dielectric layer 110 and may cure damage generated in the first dielectric layer 110, for example, during ion injection. The second thermal treatment stage may further limit or even prevent leakage current generation in operation of a memory device including the gate structure of FIG. 17 or 18. The second annealing may cure defects generated in the first dielectric layer 110 as noted previously.

The nano crystals 130_NC may be formed before application of the higher temperature second thermal treatment stage shown in FIG. 4B. The first annealing thermal treatment process may provide a nano crystal arrangement in a single layer and may form nano crystals having a thickness of about 3 to about 7 nm in diameter The nano crystals 130_NC may have a diameter from about 1 nm to about 7 nm and a spacing between ones of the nano crystals between about 1 nm and about 7 nm in some embodiments.

While operations related to injecting ions of the selected element generally refer to a substantially single layer structure in the description above, it will understood that, as discussed for various embodiments previously, a multilayer structure of the charge storing nano crystals 130_NC may be provided by injecting ions at a plurality of different height locations relative the substrate 100 in the metal oxide dielectric layer 110 and thermally treating the substrate 100 and the dielectric layer 110 to provide a multi-layer structure of overlapping ones of the discrete charge storing nano crystals 130_NC. Similarly, ions may be injected into first ion injection energy to form a first charge storing layer on the tunnel dielectric layer 135a, 135b and injecting ions at a second ion injection energy, less than the first ion injection energy, to form a second charge storing layer on the first charge storing layer with a region therebetween substantially free of implanted ions, where substantially free allows for some amount of ion implantation in the intermediate regions due to the delta projection range of the ion injection process.

As described previously, the charge trapping layer structure illustrated in FIG. 5 may be included in various integrated circuit devices such as those illustrated in FIG. 6 and FIGS. 8 through 11. It will be further understood that the charge trapping structures shown in FIG. 17 and/or FIG. 18 may similarly be used in the memory device structures shown in FIG. 6 and FIGS. 8 through 11, with the structure 150a, 150b used where the notation 150 structure is shown in these figures. For example, with reference to FIG. 17 and FIG. 6, the structure of FIG. 6 may be provided with the tunneling oxide layer 135a (110a) having a thickness of under about 9 nm and a compact (dense) structure having a dielectric constant of over about 7 and an energy band gap of over about 5 eV and may be configured to allow electron tunneling of electrons into a floating gate defined by the discrete charge storing nano crystals 130_NC through the tunneling oxide layer 135a. Spacing may be provided between the charge storing nano crystals 130_NC of about 3 to about 7 nm to limit or even prevent an undesired lateral diffusion of charges between the discrete charge storing nano crystals 130_NC. The coupling and blocking dielectric layer 140a may operate to limit or block movement of charges stored on the discrete charge storing nano crystals 130_NC towards the control gate 160 when voltage is applied to the control gate 160 during operation of the device.

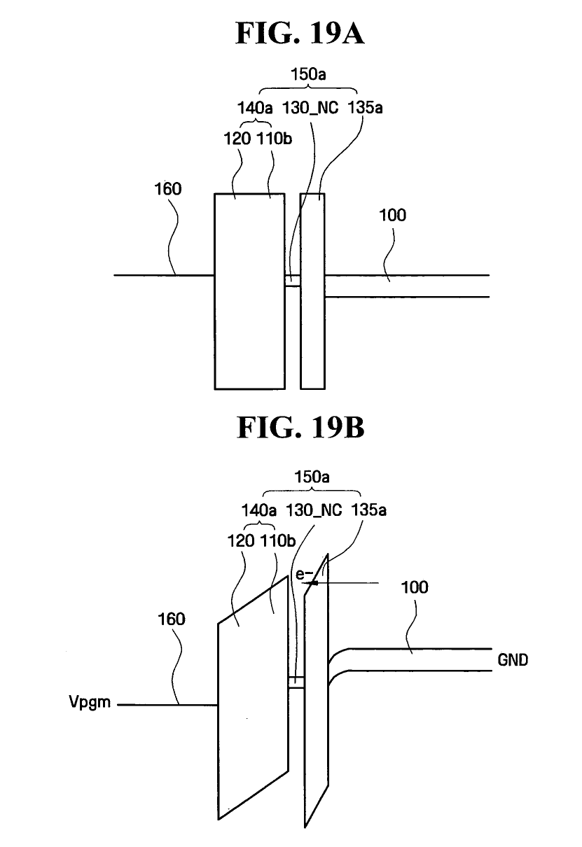

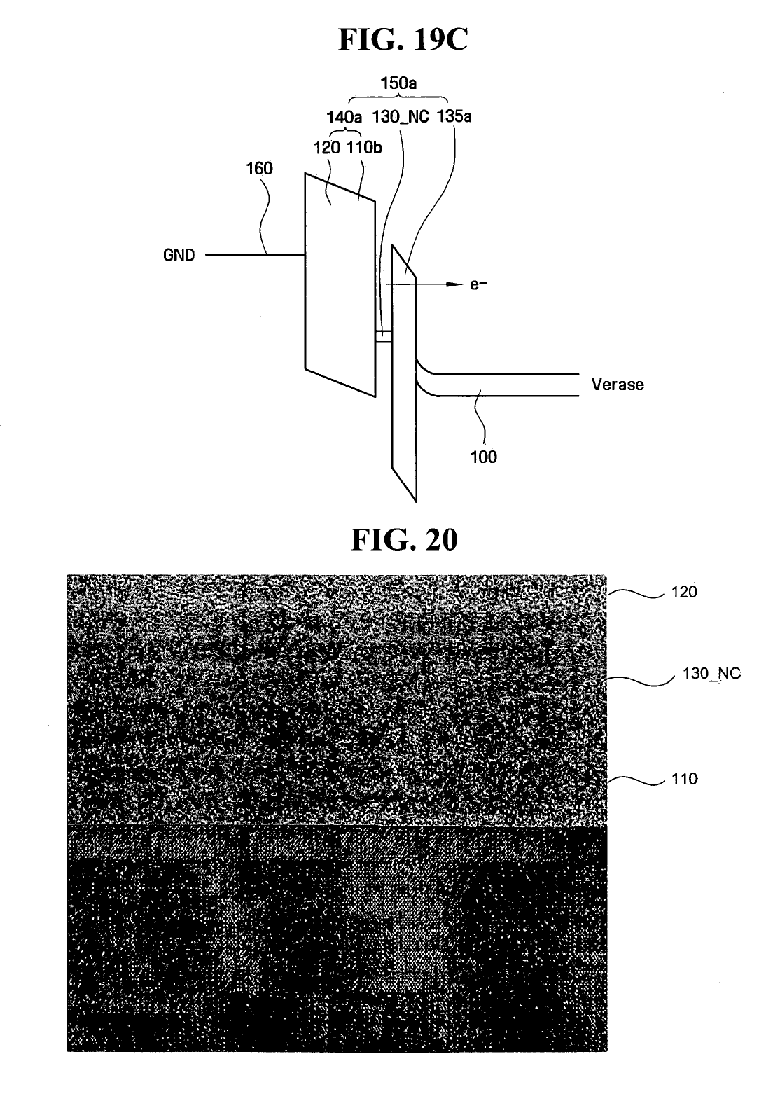

Operation of a gate structure including the charge trapping layer structure 150a of FIG. 17 will now be further described with reference to the energy band diagram illustrations of FIGS. 19A through 19C. Referring first to FIG. 19A, an initial state of the energy band diagram is illustrated. As shown in FIG. 19A, the energy band gap of the first dielectric layer 110 and the second dielectric layer 120 is about 8.7 eV and its dielectric constant is 9, where the material if both the first 110 and second 120 dielectric layer is aluminum oxide. The energy band gap of the germanium nano crystals 130_NC is about 0.66 eV where germanium is the selected ion used for implantation and formation of nano crystals. For the illustrated examples of FIGS. 19A through 19C, the control gate is aluminum and the tunneling oxide layer 135 has a thickness of about 9 nm. A mean diameter of the germanium nano crystals 130_NC is about 4 nm in a substantially single layer structure. A thickness of the coupling and blocking layer 140a of aluminum oxide is about 17 nm.

A program operation state is illustrated in the energy band diagram of FIG. 19B. As shown in FIG. 19B, when a positive programming voltage V_{pgm} is applied to the control gate 160 and the ground voltage GND is applied to the substrate 100, an electron from the channel region 100 may be trapped in the germanium nano crystals 130_NC by FN tunneling through the tunnel oxide layer 135a.

In some embodiments, when a positive programming voltage (V_{PGM}) is applied to the control gate 160, and a high voltage, substantially similar to the PGM is applied to the source region 170S and a ground voltage (GND) is applied to the drain region 170D, a hot carrier electron generated adjacent the source region 170S can be injected into the germanium nano crystals 130_NC through the tunnel oxide layer 135A as shown by the solid arrow line in FIG. 19B.

If, during the program operation, a coupling ratio of the voltage applied to the control gate 160 is high, a higher voltage may be transferred to the nanocrystals 130_NC. This may induce an effective injection of the FN tunneling or hot carrier electron injection described above. In other words, in some embodiments of the present invention, a non-volatile memory device may be provided that operates at a high speed using the coupling and blocking layer 140A formed of a high dielectric constant material having a dielectric constant of at least about 4.

Referring now to FIG. 19C, an energy band diagram is illustrated for an erase operation state. As shown in FIG. 19C, when a ground voltage GND is applied to the control gate 160 and a negative erase voltage Vₑᵣₐₛₑ is applied to the substrate 100, charge trapped in the nano crystals 130_NC may be radiated towards the substrate 100 by FN tunneling or hot hole injection as illustrated by the solid arrow line in FIG. 19C.

Referring now to the transmissive electron microscopy (TEM) photograph of a high dielectric constant charge trap double layer 150a (see FIG. 17) shown in FIG. 20, some embodiments of the present invention will be further described. In the photograph illustration of FIG. 20, the first dielectric layer 110 is an aluminum oxide layer having a thickness of about 20 nanometers formed on a p-type substrate 100 by atomic layer deposition. The selected element for ion injection is germanium injected at an ion injection energy of about 10 keV and an ion projection dose of about 1 times 10¹⁶/cm² into the aluminum oxide layer 110. The second dielectric layer 120 is also an aluminum oxide layer and has a thickness of about 10 nanometers. Thermal annealing to form the nano crystals 130_NC is performed at a temperature of about 800° C. for about thirty minutes in a nitrogen (N₂) atmosphere.

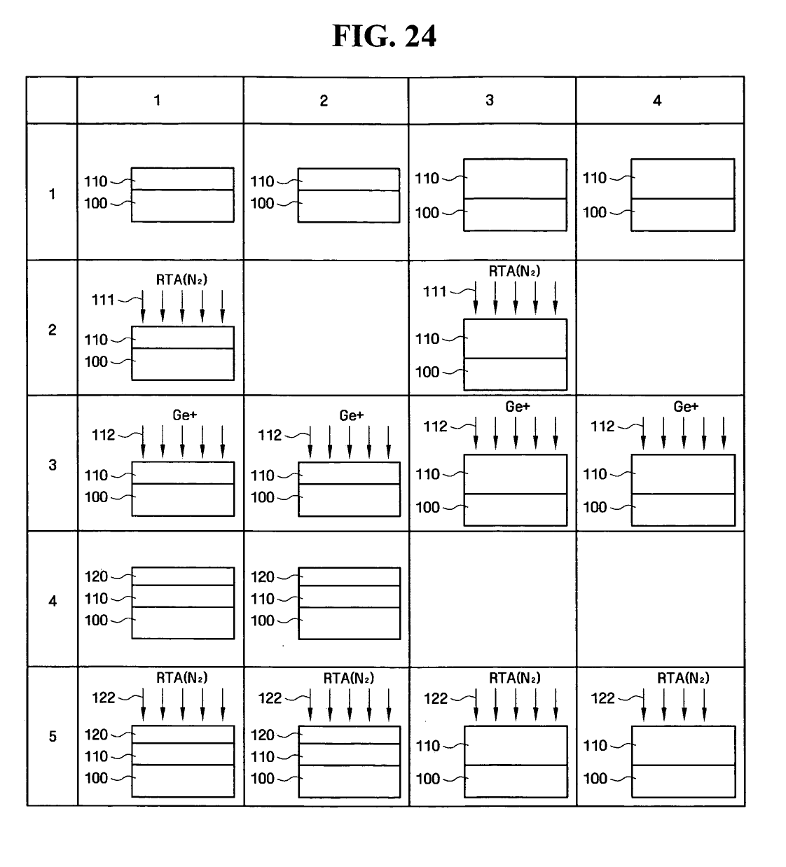

In addition to the thermal annealing to form the nano crystals 130_NC, the embodiments illustrated in FIG. 20 are also subjected to a rapid thermal anneal prior to ion injection as will be further described with reference to FIG. 24 herein. For the embodiments shown in FIG. 20, the preanneal is a rapid thermal anneal at a temperature of about 950° C. for a time of about 30 minutes in a nitrogen (N₂) atmosphere. Note that the illustrated nano crystals in FIG. 20 are a single layer structure rather than a multilayer structure.

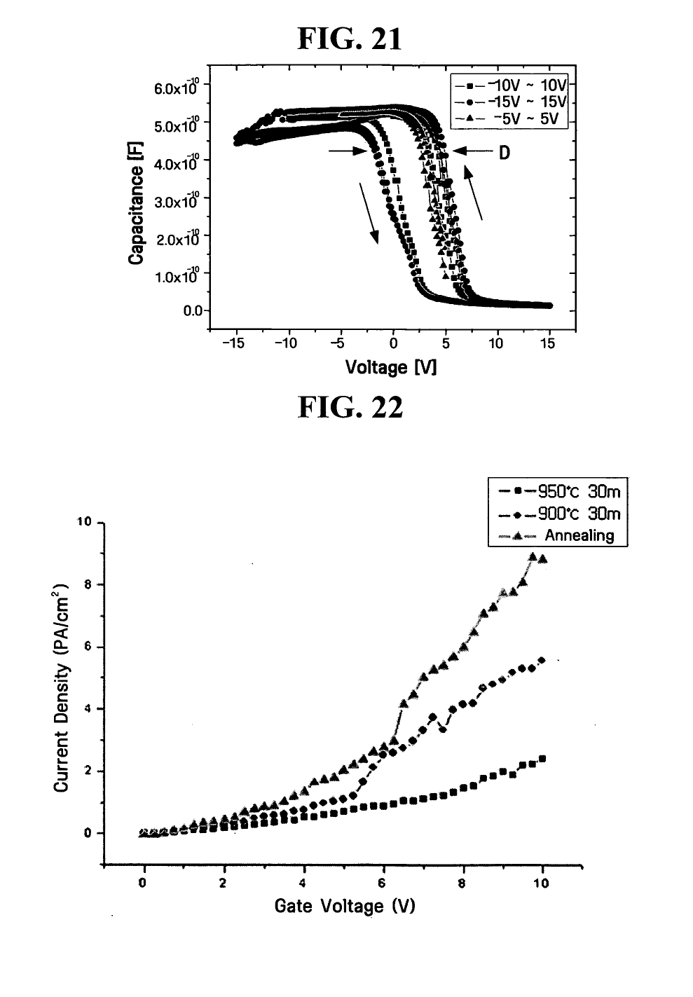

Some embodiments of the present invention will now be further described with reference to the capacitance-voltage (C-V) hysteresis curve illustrated in FIG. 21. FIG. 21 illustrates a capacitance-voltage hysteresis curve for an integrated circuit nonvolatile memory device including the charge trap double layer structure illustrated in FIG. 20 and having an aluminum control gate on the charge trap double layer structure of FIG. 20. As seen in FIG. 21, some embodiments of the present invention provide a counterclockwise hysteresis characteristic. Furthermore, as a range of the applied voltage increases, the hysteresis width D increases through increasing the positive flat-band voltage shift. As a result, as the applied voltage increases, the number of electrons that may be trapped in the germanium nano crystal generally increases, thereby allowing accumulation of more charge in the floating gate structure provided by the nano crystals 130_NC. As a result, some embodiments of the present invention may provide a counterclockwise hysteresis characteristic suitable for use in various integrated circuit memory devices.

Note that, for metal oxide first dielectric layer 110 embodiments described herein, if a thickness of the first dielectric layer 110 is overly reduced, a clockwise hysteresis may result, which clockwise hysteresis structure may not be suitable for use in integrated circuit memory devices. For example, where aluminum oxide is used as the first dielectric layer 110, a thicknesses thereof of below about 20 nanometers may cause such a clockwise hysteresis. In addition, for embodiments using the double layer charge trapping structure 150a shown in FIG. 17, an improved hysteresis characteristic may be provided where a thickness of the second dielectric layer 120 is under about 10 nanometers.

As noted above, some embodiments of the present invention provide for a thermal treatment before injection of ions into the first dielectric layer 110. FIG. 22 is a graph illustrating leakage current characteristics for different annealing temperatures for the thermal treatment preceding ion injection for some embodiments of the present invention. The graphs illustrated in FIG. 22 are based on a structure and processing conditions substantially as described with reference to FIG. 20 for three different pre-ion injection annealing conditions. The three conditions illustrated by the respective graphs in FIG. 22 correspond to no pre-annealing, pre-annealing at about 900° C. for about thirty minutes and pre-annealing at about 950° C. for about thirty minutes. Thus, as illustrated in FIG. 22, in some embodiments of the present invention, pre-ion injection annealing at about 950° C. may effectively reduce leakage current in the resulting device. Furthermore, annealing at other, lower temperatures may also reduce leakage current as compared to embodiments in which no pre-annealing is performed.

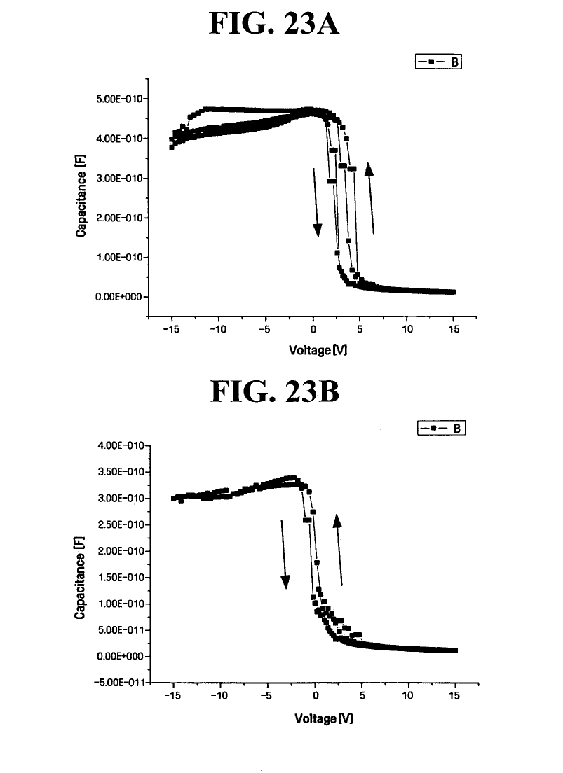

Referring now to the C-V hysteresis curves of FIGS. 23A and 23B, further embodiments of the present invention using the single layer charge trap structure 150b shown in FIG. 18 will now be further described. More particularly, FIG. 23A illustrates a C-V hysteresis curve where an aluminum oxide first dielectric layer 110 having a thickness of about 20 nanometers is provided. FIG. 23B corresponds to an aluminum oxide first dielectric layer 110 having a thickness of about 60 nanometers. In each case, the first dielectric layer 110 may be grown on the substrate 100 by an atomic layer deposition process on a p-type substrate 100. For both figures, a pre-injection rapid thermal anneal is performed in a nitrogen (N₂) atmosphere at a temperature of about 950° C. for about thirty minutes. Germanium ions are injected at an ion projection does of about 1×10¹⁶/cm² at an ion injection energy of about 10 keV. Thermal annealing subsequently, to form the nano crystals 130_NC, is performed in a nitrogen (N₂) atmosphere at a temperature of about 950° C. for about thirty minutes. Note that a counterclockwise hysteresis characteristic is shown for both FIGS. 23A and 23B. Furthermore, as the thickness of the single layer 110 increases from FIG. 23A to 23B, the hysteresis width may vary.

Embodiments of the present invention will now be further described with reference to the schematic cross sectional illustrations of FIG. 24. As shown in FIG. 24, four different processes for formation of a gate structure according to embodiments of the present invention are presented in the four respective columns, with respective sequential operations shown in corresponding rows for each process. In all four columns, forming a gate structure for an integrated circuit memory device includes forming a metal oxide dielectric layer 110 on an integrated circuit substrate 100. For the embodiments illustrated in columns 1 and 3, as described above with reference to FIG. 20, a thermal treatment is provided prior to ion injection. Thus, as shown in row 2 of FIG. 24, injecting ions is preceded by thermally treating 111 the substrate 100 including the metal oxide dielectric layer 110. More particularly, columns 1 and 3 indicate a rapid thermal annealing process in a nitrogen (N₂) atmosphere. A temperature over a crystallization temperature of the metal oxide dielectric layer 110 may be used for the rapid thermal annealing process 111 illustrated in row 2 of FIG. 24. In some embodiments, the rapid thermal annealing process 111 is performed at about 950° C. in a nitrogen atmosphere.

Shown in row 3 of FIG. 24, for all four processes, is ion injection 112 of ions of a selected element from group 4 of the Periodic Table into the dielectric layer 110. More particularly, germanium ions are shown as being injected 112 into the dielectric layer 110 in each of the four columns of row 3 in FIG. 24.

Note that a thicker layer 110 is shown in each of columns 3 and 4 than in columns 1 and 2. For example, a thickness of about 30 nanometers may be used for the dielectric layer 110 in the embodiments shown in columns 3 and 4, while a thickness of about 20 nanometers may be used for the embodiments shown in columns 1 and 2.

Operations relative to the embodiments in columns 1 and 2 differ from columns 3 and 4 in that the formation of a second dielectric layer 120 on the first dielectric layer 110 is shown in row 4 for the embodiments illustrated in columns 1 and 2. The second dielectric layer 120 may be a metal oxide layer and may have a thickness of less than about 10 nanometers. The second dielectric layer 120 in the embodiments of columns 1 and/or 2 may be the same material as the first dielectric layer 110. Finally, columns 1-4 in row 5 each show a rapid thermal annealing process 122 for forming the nano crystals 130-NC in the dielectric layer 110 to provide the structure described previously with reference to FIG. 17 (for columns 1 and 2) and FIG. 18 (for columns 3 and 4).

In some embodiments, the conditions for the rapid thermal annealing operations at column 5 may vary depending upon whether the pre-anneal, as shown at row 2 of FIG. 24, is provided. In other words, a different thermal treatment at row 5 may be used for the embodiments of column 2 than for the embodiments of column 1. Similarly, a different thermal treatment may be used for the embodiments of column 4 than for the embodiments of column 3. For example, when using a single step annealing process, such as illustrated in FIG. 4A, where a pre-annealing is used as in the embodiments shown in columns 1 and 3 of FIG. 24, the annealing in row 5 of FIG. 24 may proceed at a temperature of about 700° C. to about 900° C. for a time from about 5 minutes to about 30 minutes. Where the pre-anneal shown in row 2 of FIG. 24 is not used, as in column 2 and column 4 of FIG. 24, the annealing at row 5 of FIG. 24 may proceed at a higher temperature of about 900° C. to about 950° C. The anneal time may still be for a time of about 5 minutes to about 30 minutes.

In some embodiments of the present invention, germanium ion are injected at an angle of 7 degrees into an aluminum oxide (Al₂O₃) target layer having a thickness of 200 Å at respective ion injection energies of 7 keV and 10 keV. Simulation results for such embodiments show a mean injection depth (Rₚ) of about 100 Å to about 170 Å with a delta projection range of about 20 Å to about 60 Å. Some simulation results at 10 keV show a mean injection depth (Rₚ) of about 131 Å with a delta projection range of about 30 Å. In some embodiments, injecting ions includes injecting the ions at a selected mean injection depth and with a delta projection range of from about 20 Å to about 160 Å.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of forming a gate structure for an integrated circuit memory device, comprising:
forming a metal oxide dielectric layer on an integrated circuit substrate;
injecting ions of a selected element from group 4 of the periodic table and having a thermal diffusivity of less than about 0.5 centimeters per second (cm²/s) into the dielectric layer to form a charge storing region in the dielectric layer with a tunnel dielectric layer under the charge storing region and a capping dielectric layer above the charge storing region;
thermally treating the substrate including the metal oxide dielectric layer to form a plurality of discrete charge storing nano crystals in the charge storing region; and
forming a gate electrode layer on the dielectric layer.

2. The method of claim 1, wherein the metal oxide dielectric layer comprises an oxide and/or oxynitride of aluminum, hafnium, titanium, zirconium, scandium, yttrium and/or lanthanum having a dielectric constant of over 7 and wherein the selected element comprises germanium (Ge).

3. The method of claim 1, wherein injecting ions comprises injecting the ions at an injection energy of less than about 10000 electron volts (eV).

4. The method of claim 3 wherein injecting ions comprises injecting the ions at an injection energy of greater than 5000 electron volts (eV).

5. The method of claim 4, wherein a thickness of the metal oxide dielectric layer formed on the substrate is less than about 30 nm.

6. The method of claim 1, wherein injecting ions is preceded by thermally treating the substrate including the metal oxide dielectric layer.

7. The method of claim 6, wherein injecting ions is preceded by thermally treating the substrate including the metal oxide dielectric layer at a temperature over a crystallization temperature of the metal oxide dielectric layer.

8. The method of claim 7, wherein injecting ions is preceded by thermally treating the substrate including the metal oxide dielectric layer at a temperature of at least about 950° C. in a nitrogen atmosphere.

9. The method of claim 7, wherein thermally treating the substrate after injecting ions comprises rapid thermal annealing the substrate including the metal oxide dielectric layer about 700° C. to about 900° C. for about 5 minutes to about 30 minutes.

10. The method of claim 9, wherein rapid thermal annealing is followed by a second rapid thermal annealing at about 900° C. to about 1050° C. for about 5 minutes to about 30 minutes.

11. The method of claim 1, wherein thermally treating the substrate after injecting ions comprises rapid thermal annealing the substrate including the metal oxide dielectric layer at about 900° C. to about 950° C. for about 5 minutes to about 30 minutes.

12. The method of claim 1, wherein a thickness of the metal oxide dielectric layer is less than about 30 nanometers (nm).

13. The method of claim 12, wherein a thickness of the tunnel dielectric layer is less than about 9 nm.

14. The method of claim 1, wherein injecting ions comprises injecting the ions at a mean injection depth selected based on a thickness of the metal oxide dielectric layer and with a delta projection range of no more than about 7 nanometers (nm).

15. The method of claim 14, wherein injecting ions comprises injecting the ions with a delta projection range of from about 20 angstroms (Å) to about 60 Å.

16. The method of claim 1, wherein the metal oxide dielectric layer has an energy band gap of at least about 5 electron volts (eV).

17. The method of claim 1, wherein injecting ions comprises injecting the ions at an ion injection energy of greater than 7000 electron volts (eV) and less than about 10000 eV and at an ion projection dose from about 1×10¹⁴/cm² to about 2×10¹⁶/cm².

18. The method of claim 1, wherein the nano crystals have a diameter from about 1 nm to about 7 nm and a spacing between ones of the nano crystals is between about 1 nm and about 7 nm.

19. The method of claim 1, wherein injecting ions comprises:
injecting ions of the selected element at a first ion injection energy to form a first charge storing layer on the tunnel dielectric layer; and
injecting ions of the selected element at a second ion injection energy, less than the first ion injection energy, to form a second charge storing layer on the first charge storing layer with a region therebetween substantially free of implanted ions.

20. The method of claim 1 wherein injecting ions includes injecting ions at a plurality of different height locations relative to the substrate in the metal oxide dielectric layer and wherein thermally treating the substrate provides a multi-layer structure of overlapping ones of the discrete charge storing nano crystals.

21. The method of claim 1, wherein forming the metal oxide dielectric layer is preceded by forming a common gate on a gate dielectric layer on the substrate and wherein forming the metal oxide dielectric layer and implanting ions are carried out on sidewalls of the common gate electrode and on a channel portion of the substrate proximate respective sides of the common gate and wherein forming the gate electrode layer comprises forming sidewall gates on the second dielectric layer proximate the respective sides of the common gate and extending over the channel portion.

22. The method of claim 1, wherein forming the metal oxide dielectric layer is preceded by forming a channel region including a recess region and a step region adjacent the recess region extending between a source and a drain region in the substrate and wherein forming the metal oxide dielectric layer, implanting ions and forming the gate electrode are carried out on the channel region including the recess region and the step region.

23. The method of claim 21, wherein the recess region has a rounded portion.

24. The method of claim 1, wherein the integrated circuit device comprises a non-volatile memory device or a dynamic random access memory (DRAM).

25. The method of claim 23, wherein the integrated circuit device comprises a flash memory and wherein the charge storing region comprises a floating gate of a cell of the flash memory.

26. The method of claim 1, wherein the metal oxide dielectric layer comprises a first dielectric layer and wherein the method further comprises, between injecting ions and thermally treating the substrate, forming a second dielectric layer on the metal oxide dielectric layer, the second dielectric layer comprising a metal oxide.

27. The method of claim 26, wherein the second dielectric layer has a thickness of less than about 10 nm.

28. The method of claim 26, wherein the first and second dielectric layer comprise a same material.

29. The method of claim 26, wherein the first and second dielectric layer comprise an oxide and/or oxynitride of aluminum, hafnium, titanium, zirconium, scandium, yttrium and/or lanthanum and wherein the selected element comprises germanium (Ge).

30. The method of claim 26, wherein injecting ions comprises injecting the ions at an injection energy of less than about 10000 electron volts (eV).

31. The method of claim 30 wherein injecting ions comprises injecting the ions at an injection energy of greater than 7000 electron volts (eV).

32. The method of claim 31, wherein a thickness of the metal oxide dielectric layer formed on the substrate is less than about 20 nm.

33. The method of claim 26, wherein injecting ions is preceded by thermally treating the substrate including the first dielectric layer.

34. The method of claim 33, wherein injecting ions is preceded by thermally treating the substrate including the first dielectric layer at a temperature over a crystallization temperature of the first dielectric layer.

35. The method of claim 26, wherein injecting ions comprises injecting the ions at a selected mean injection depth and with a delta projection range of no more than about 7 nanometers (nm).

36. The method of claim 26, wherein injecting ions comprises injecting the ions at an ion injection energy of greater than 7000 electron volts (eV) and at an ion projection dose from about 1×10¹⁴/cm² to about 2×10¹⁶/cm².

37. The method of claim 36, wherein the ion injection energy is no more than about 10000 eV.

38. The method of claim 26, wherein forming the second dielectric layer comprises forming the second dielectric layer by atomic layer deposition (ALD) and/or plasma enhanced chemical vapor deposition (PECVD).

39. The method of claim 26, wherein forming the first dielectric layer is preceded by forming a common gate on a gate dielectric layer on the substrate and wherein forming the first dielectric layer, implanting ions and forming the second dielectric layer are carried out on sidewalls of the common gate electrode and on a channel portion of the substrate proximate respective sides of the common gate and wherein forming the gate electrode layer comprises forming sidewall gates on the second dielectric layer proximate the respective sides of the common gate and extending over the channel portion.

40. The method of claim 26, wherein forming the first dielectric layer is preceded by forming a channel region including a recess region and a step region adjacent the recess region extending between a source and a drain region in the substrate and wherein forming the first dielectric layer, implanting ions and forming the second dielectric layer and gate electrode are carried out on the channel region including the recess region and the step region.

41. The method of claim 40, wherein the recess region has a rounded portion.

42. The method of claim 26, wherein the integrated circuit device comprises a non-volatile memory device or a dynamic random access memory (DRAM).

43. The method of claim 42, wherein the integrated circuit device comprises a flash memory and wherein the charge storing region comprises a floating gate of a cell of the flash memory.

44. A method of forming a gate structure for an integrated circuit memory device, comprising:
forming a metal oxide dielectric layer on an integrated circuit substrate;
thermally treating the substrate including the metal oxide dielectric layer at a temperature over a crystallization temperature of the metal oxide dielectric layer;
injecting ions of germanium (Ge) into the thermally treated first dielectric layer at an ion injection energy of less than about 10000 electron volts (eV) and at an ion projection dose from about 1×10¹⁴/cm² to about 2×10¹⁶/cm² to form a charge storing region in the metal oxide dielectric layer with a tunnel dielectric layer under the charge storing region and a capping dielectric layer above the charge storing region;
rapid thermal annealing the substrate including the first dielectric layer and the second dielectric layer at about 700° C. to about 900° C. for about 5 minutes to about 30 minutes to form a plurality of discrete charge storing nano crystals in the charge storing region; and
forming a gate electrode layer on the second dielectric layer.

45. The method of claim 44, wherein the metal oxide dielectric layer comprises a first dielectric layer and wherein the method further comprises, between injecting ions and rapid thermal annealing, forming a second dielectric layer on the metal oxide dielectric layer, the second dielectric layer comprising a metal oxide, and wherein the second dielectric layer has a thickness of less than about 10 nm.

46. A gate structure for an integrated circuit device, comprising:
an integrated circuit substrate;
a metal oxide dielectric layer on the substrate, the metal oxide dielectric layer including a tunnel dielectric layer on the substrate, a charge storing layer including a plurality of discrete nano-crystals of a selected element from group 4 of the periodic table and having a thermal diffusivity of less than about 0.5 centimeters per second (cm²/s) on the tunnel dielectric layer and a capping dielectric layer on the charge storing layer; and
a gate electrode layer on the capping dielectric layer.

47. The gate structure of claim 46, wherein the metal oxide dielectric layer comprises a first dielectric layer and wherein the gate structure further comprises a second dielectric layer interposed between the capping dielectric layer and the gate electrode layer, the second dielectric layer comprising a metal oxide and having a thickness of less than about 10 nm.

48. The gate structure of claim 47, wherein the first dielectric layer has a thickness of no more than about 20 nm.

49. The gate structure of claim 47, wherein the first and second dielectric layers comprise an oxide and/or oxynitride of aluminum, hafnium, titanium, zirconium, scandium, yttrium and/or lanthanum.

50. The gate structure of claim 46, wherein the tunnel dielectric layer has a thickness of no more than about 9 mm.

51. The gate structure of claim 46, wherein the nano crystals have a diameter from about 1 nm to about 7 nm and a spacing between ones of the nano crystals is between about 1 nm and about 7 nm.

52. The gate structure of claim 46 wherein the charge storing region includes a multi-layer structure of overlapping ones of the discrete charge storing nano crystals.

53. The gate structure of claim 46, wherein the integrated circuit device comprises a non-volatile memory device or a dynamic random access memory (DRAM).

54. The gate structure of claim 46, wherein the integrated circuit device comprises a flash memory device and wherein the charge storing region comprises a floating gate of a cell of the flash memory device.

55. A memory cell including the gate structure of claim 46, the memory cell further comprising a common gate on a gate dielectric layer on the substrate and wherein the metal oxide dielectric layer extends along sidewalls of the common gate electrode and on a channel portion of the substrate proximate respective sides of the common gate and wherein the memory cell further includes sidewall gates on the metal oxide dielectric layer proximate the respective sides of the common gate and extending over the channel portion.

56. A memory cell including the gate structure of claim 46, the memory cell further comprising a channel region including a recess region and a step region adjacent the recess region extending between a source and a drain region in the substrate and wherein the metal oxide dielectric layer extends along the channel region including the recess region and the step region.

57. The memory cell of claim 56, wherein the recess region has a rounded portion.
